(19) United States
(12) Patent Application Publication
(10) Pub. No.: US 2022/0320261 A1
(43) Pub. Date: Oct. 6, 2022

(54) DISPLAY DEVICE

(71) Applicant: Japan Display Inc., Tokyo (JP)

(72) Inventor: Kenji HARADA, Tokyo (JP)

(73) Assignee: Japan Display Inc., Tokyo (JP)

(21) Appl. No.: 17/657,258

(22) Filed: Mar. 30, 2022

(30) Foreign Application Priority Data
Apr. 6, 2021 (JP) 2021-064806

(51) Int. Cl. H01L 27/32; H01L 51/52

(52) U.S. Cl. CPC H01L 27/3279; H01L 51/5228

(57) ABSTRACT

According to one embodiment, a display device includes a first power line located at a first end portion of a non-display region, a second power line located at a second end portion, a first auxiliary line disposed at a corner portion of a display region, and a second auxiliary line disposed on a center portion side of the display region, wherein the first auxiliary line includes a first resistance adjustment portion that adjusts resistance of the first auxiliary line, the second auxiliary line includes a second resistance adjustment portion that adjusts resistance of the second auxiliary line, and a first length of the first resistance adjustment portion is longer than a second length of the second resistance adjustment portion.

### CROSS-REFERENCE TO RELATED APPLICATIONS

This application is based upon and claims the benefit of priority from Japanese Patent Application No. 2021-064806, filed Apr. 6, 2021, the entire contents of which are incorporated herein by reference.

### FIELD

Embodiments of the present invention relate to a display device.

### BACKGROUND

In recent years, a display device in which an organic light-emitting diode (OLED) (alternatively referred to as an organic electro-luminescence (EL) element in some cases) is used as a display element has been put into practical use. The display element includes an organic layer between a pixel electrode and a common electrode. The organic layer includes functional layers such as a hole-transport layer and an electron-transport layer in addition to an emitting layer. Such an organic layer is formed by, for example, a vacuum vapor deposition method.

When cathode resistance is high as in a display device or the like having an ultra-high definition panel used for virtual reality (VR) or the like, a voltage drop is likely to occur in a cathode electrode, a voltage applied to each organic EL element of a display surface becomes uneven, and display performance may be deteriorated due to a voltage gradient such as partial degradation of a light emission intensity on the display surface.

### BRIEF DESCRIPTION OF THE DRAWINGS

FIG. 1 is a diagram showing a configuration example of a display device according to an embodiment.

FIG. 2 is a plan view showing a configuration example of a pixel according to the embodiment.

FIG. 3 is a cross-sectional view showing a configuration example of the display device taken along line A-A shown in FIG. 2.

FIG. 4 is a plan view showing a configuration example of an auxiliary line according to the embodiment.

FIG. 5 is a cross-sectional view of the display device taken along line B-B shown in FIG. 4.

FIG. 6 is a plan view showing a configuration example of a peripheral line according to Modified Example 1.

FIG. 7 is a cross-sectional view of the display device taken along line B-B shown in FIG. 6.

FIG. 8 is a plan view showing a configuration example of a display region according to Modified Example 2.

FIG. 9 is a plan view showing a configuration example of an auxiliary line according to Modified Example 3.

FIG. 10 is a plan view showing a configuration example of a pixel according to Modified Example 4.

FIG. 11 is a plan view showing a configuration example of a pixel according to Modified Example 5.

### DETAILED DESCRIPTION

According to one embodiment, a display device includes a first power line located at a first end portion of a non-display region located around a display region in which a plurality of pixels are disposed and that includes a rounded corner portion; a second power line located at a second end portion on a side opposite to the first end portion of the non-display region in a first direction; a first auxiliary line extending in the first direction, connected to the first power line and the second power line, and disposed at the corner portion; and a second auxiliary line extending in the first direction, connected to the first power line and the second power line, and disposed on a center portion side of the display region in a second direction intersecting the first direction, wherein the first auxiliary line includes a first resistance adjustment portion that is located in the non-display region and adjusts resistance of the first auxiliary line, the second auxiliary line includes a second resistance adjustment portion that is located in the non-display region and adjusts resistance of the second auxiliary line, and a first length of the first resistance adjustment portion is longer than a second length of the second resistance adjustment portion.

According to another embodiment, a display device includes a first power line located at a first end portion of a non-display region located around a display region in which a plurality of pixels are disposed and that includes a rounded corner portion; a second power line located at a second end portion on a side opposite to the first end portion of the non-display region in a first direction; a plurality of first auxiliary lines extending in the first direction and disposed in a first region including the corner portion of the display region; and a plurality of second auxiliary lines extending in the first direction and disposed in a second region including a central portion of the display region in a second direction intersecting the first direction, wherein the first auxiliary lines are connected to the first power line and the second power line at a first interval in the second direction, and the second auxiliary lines are connected to the first power line and the second power line at a second interval smaller than the first interval in the second direction.

According to another embodiment, a display device includes a first power line located at a first end portion of a non-display region located around a display region in which a plurality of pixels are disposed and that includes a rounded corner portion; a second power line located at a second end portion on a side opposite to the first end portion of the non-display region in a first direction; a first peripheral line located in the non-display region, extending in the first direction, and connected to the first power line; a second peripheral line located in the non-display region, extending in the first direction, and connected to the second power line; a third peripheral line located closer to a central portion of the display region than the first peripheral line is in a second direction intersecting the first direction in the non-display region, extending in the first direction, and connected to the first power line; a fourth peripheral line located closer to the central portion of the display region than the second peripheral line is in the second direction in the non-display region, extending in the first direction, and connected to the second power line; a first auxiliary line extending in the first direction, connected to the first peripheral line and the third peripheral line, and disposed at the corner portion; and a second auxiliary line extending in the first direction and connected to the second peripheral line and the fourth peripheral line, wherein the first peripheral line and the third peripheral line include a first resistance adjustment portion that adjusts resistance from the first peripheral line to the third peripheral line, the second peripheral line and the fourth peripheral line include a second resistance adjustment portion that adjusts resistance from the second peripheral line to the fourth peripheral line, and a first length of the first resistance adjustment portion is longer than a second length of the second resistance adjustment portion.

According to the present invention, it is possible to provide a display device capable of improving display quality.

Embodiments will be described hereinafter with reference to the accompanying drawings.

The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the X axis is referred to as an X direction or a first direction, a direction along the Y axis is referred to as a Y direction or a second direction and direction along the Z axis is referred to as a Z direction or a third direction. The first direction X, the second direction Y and the third direction Z may intersect at an angle other than ninety degrees. The length taken along the first direction X or second direction Y may be referred to as “width”, and the length taken along the third direction Z may be referred to as “thickness”. In the following descriptions, a direction from a substrate 10 to a display element 20 may be referred to as “upward” (or simply “up” or “above”) and a direction from the display element 20 to the substrate 10 may be referred to as “downward” (or simply “down” or “below”). With such expressions “a second member above a first member” and “a second member below a first member”, the second member may be in contact with the first member or may be remote from the first member. A plane defined by the X axis (the first direction X) and the Y axis (the second direction Y) may be referred to as an X-Y plane, a plane defined by the X axis (the first direction X) and the Z axis (the third direction Z) may be referred to as an X-Z plane, and a plane defined by the Y axis (the second direction Y) and the Z axis (the third direction Z) may be referred to as an Y-Z plane. Further, viewing towards the X-Y plane is referred to as planar view.

### EMBODIMENTS

The display device DSP of the embodiments is an organic electroluminescent display element comprising an organic light-emitting diode (OLED) as a display element, and can be mounted on TV receivers, personal computers, tablet terminals, mobile telephone terminals and the like.

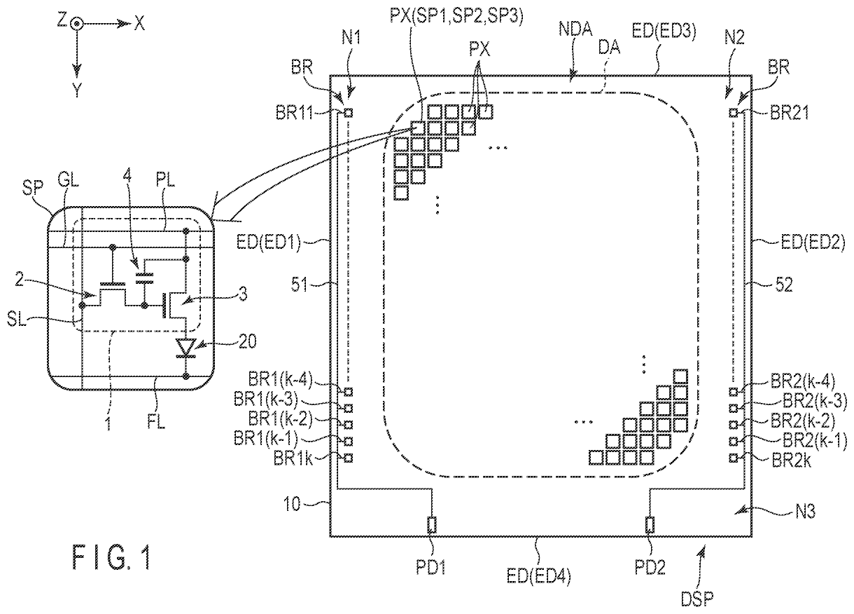

FIG. 1 is a diagram showing a configuration example of a display device DSP according to an embodiment.

The display device DSP includes an insulating substrate 10. The substrate 10 may be glass or a resin film having flexibility. In the example shown in FIG. 1, the display device DSP has a rectangular shape in which the length of the display device DSP in a second direction Y is longer than the length of the display device DSP in a first direction X. Incidentally, the display device DSP may have a rectangular shape (hereinafter referred to as a round shape in some cases) in which the length of the display device DSP in the second direction Y is longer than the length of the display device DSP in the first direction X and corner portions are rounded, or may have a shape other than the rectangular shape and the round shape. In addition, the display device DSP has a display region DA for displaying an image and a non-display region NDA located around (alternatively at the periphery of) the display region DA. The display region DA has a round shape in which the length of the display region DA in the second direction Y is longer than the length of the display region DA in the first direction X and corner portions are rounded. The display region DA is rounded at the corner portions such that the width of the display region DA in the first direction X becomes narrower toward end portions in the second direction Y. Incidentally, the display region DA may have a shape other than the round shape. The non-display region NDA has a rectangular shape in which the length of the non-display region NDA in the second direction Y is longer than the length of the non-display region NDA in the first direction X. Incidentally, the non-display region NDA may have a shape other than the rectangular shape.

The display device DSP includes a plurality of pixels PX arrayed in a matrix in the first direction X and the second direction Y in the display region DA. In the display device DSP, for example, in the display region DA, the number of pixels PX disposed in the first direction X at each of the corner portions is smaller than the number of pixels PX disposed in the first direction X at the central portion in the second direction Y. Each of the pixels PX includes a plurality of sub-pixels SP1, SP2, and SP3. In this case, each sub-pixel indicates a minimum unit that can be individually controlled according to a pixel signal, and is present, for example, in a region including a switching element disposed at a position where a scanning line GL and a signal line SL to be described later intersect each other. For example, each pixel PX includes a red sub-pixel SP1, a green sub-pixel SP2, and a blue sub-pixel SP3. Incidentally, each pixel PX may include four or more sub-pixels obtained by adding a sub-pixel of another color such as white to the sub-pixels of the above three colors.

A configuration example of one sub-pixel SP included in each pixel PX will be briefly described.

That is, the sub-pixel SP includes a pixel circuit 1 and a display element 20 that is driven and controlled by the pixel circuit 1. The pixel circuit 1 includes a pixel switch 2, a drive transistor 3, and a capacitor 4. For example, the pixel switch 2 and the drive transistor 3 are switching elements including thin-film transistors.

In the pixel switch 2, a gate electrode is connected to a scanning line GL, a source electrode is connected to a signal line SL, and a drain electrode is connected to one electrode constituting the capacitor 4 and a gate electrode of the drive transistor 3. In the drive transistor 3, a source electrode is connected to the other electrode constituting the capacitor 4 and a power line PL, and a drain electrode is connected to an anode of the display element 20. A cathode of the display element 20 is connected to a feeder line FL. Incidentally, the configuration of the pixel circuit 1 is not limited to the example shown in the drawing.

The display element 20 is an organic light-emitting diode (OLED) which is a light emitting element. For example, the sub-pixel SP1 includes a display element that emits light corresponding to a red wavelength, the sub-pixel SP2 includes a display element that emits light corresponding to a green wavelength, and the sub-pixel SP3 includes a display element that emits light corresponding to a blue wavelength. The configuration of the display element 20 will be described later.

The display device DSP has an edge portion (alternatively referred to as an end portion in some cases) ED. In the example shown in FIG. 1, the display device DSP has four edge portions ED (ED1, ED2, ED3, and ED4). The edge portions ED1 and ED2 are opposed to each other in the first direction X. In other words, the edge portion ED2 is located on the opposite side of the edge portion ED1 in the first direction X. The edge portions ED1 and ED2 are located in the order described at an interval in the first direction X. The edge portions ED3 and ED4 are opposed to each other in the second direction Y. In other words, the edge portion ED4 is located on the opposite side of the edge portion ED3 in the second direction Y. The edge portions ED3 and ED4 are located in the order described at an interval in the second direction Y. Outer end portions of the non-display region NDA are defined by the edge portions ED1 to ED4. In addition, the non-display region NDA includes a first peripheral area N1 extending in the second direction Y and located on the edge portion ED1 side, a second peripheral area N2 extending in the second direction Y and located on the edge portion ED2 side, and a third peripheral area N3 extending in the first direction X and located on the edge portion ED4 side. The first peripheral area N1, the display region DA, and the second peripheral area N2 are arranged in this order in the first direction X. A flexible printed circuit (not shown) is mounted in the third peripheral area N3.

The display device DSP includes power lines 51 and 52 located in the non-display region NDA, a plurality of peripheral lines BR (BR 11, . . . , BR1(k−4), BR1(k−3), BR1(k−2), BR1(k−1), BR1k, . . . , BR21, . . . , BR2(k−4), BR2(k−3), BR2(k−2), BR2(k−1), and BR2k), and pads PD1 and PD2. The power line 51 is located in the first peripheral area N1, and the power line 52 is located in the second peripheral area N2. The plurality of peripheral lines BR are arranged in the second direction Y in each of the first peripheral area N1 and the second peripheral area N2. In the example shown in FIG. 1, the plurality of peripheral lines BR11, . . . , BR1(k−4), BR1(k−3), BR1(k−2), BR1(k−1), and BR1k extend in the first direction X and are arranged in the second direction Y from the edge portion ED3 side to the edge portion ED4 side in the order described in the first peripheral area N1. The plurality of peripheral lines BR21, . . . , BR2 (k−4), BR2 (k−3), BR2 (k−2), BR2 (k−1), and BR2k extend in the first direction X and are arranged in the second direction Y from the edge portion ED3 side to the edge portion ED4 side in the order described in the second peripheral area N2. For example, the peripheral lines BR11 to BR1k and the peripheral lines BR21 to BR2k are opposed to each other in the first direction X and are disposed symmetrically with respect to the display region DA in the first direction X.

The power line 51 is electrically connected to the plurality of peripheral lines BR11 to BR1k located in the first peripheral area N1. In addition, the power line 51 is electrically connected to the pad PD1. The power line 52 is electrically connected to the plurality of peripheral lines BR21 to BR2k located in the second peripheral area N2. In addition, the power line 52 is electrically connected to the pad PD2.

In the display region DA, the corner portions on the edge portion ED3 side are rounded such that the width of the display region DA becomes narrower toward the edge portion ED3 side, and the corner portions on the edge portion ED4 side are rounded such that the width of the display region DA becomes narrower toward the edge portion ED4 side.

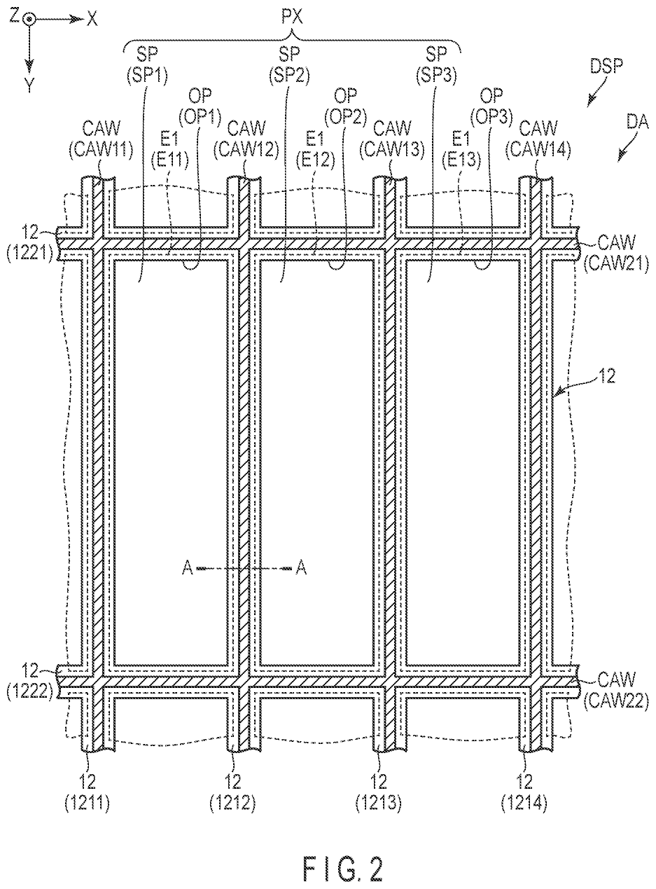

FIG. 2 is a plan view showing a configuration example of a pixel PX according to the embodiment. FIG. 2 shows only configurations necessary for description.

The display device DSP includes an insulating layer 12, a lower electrode E1, an auxiliary line CAW, and the like. In the example shown in FIG. 2, the display device DSP includes an insulating layer 12 (1211, 1212, 1213, 1214, 1221, and 1222), a lower electrode E1 (E11, E12, and E13), an auxiliary line CAW (CAW11, CAW12, CAW13, CAW14, CAW21, and CAW22), and the like.

The lower electrode E1 is disposed at a sub-pixel SP. In the example shown in FIG. 2, the lower electrode E1 includes lower electrodes E11, E12, and E13. The lower electrode E11 is disposed at the sub-pixel SP1. The lower electrode E12 is disposed at the sub-pixel SP2. The lower electrode E13 is disposed at the sub-pixel SP3. The lower electrodes E11 to E13 are arranged in the first direction X. The lower electrode including the lower electrodes E11 to E13 is an electrode disposed for each sub-pixel, alternatively for each display element, and may be referred to as a pixel electrode, an anode, or the like.

The lower electrode E1 is formed in a rectangular shape in planar view. In the example shown in FIG. 2, each of the lower electrodes E11 to E13 is formed in a rectangular shape in which a length of the lower electrode in the second direction Y is longer than a length of the lower electrode in the first direction X. The lower electrode E1 may be formed in a shape other than the rectangular shape in planar view.

The insulating layer 12 is formed in a lattice pattern in planar view. The insulating layer 12 is formed so as to partition the display elements, alternatively the sub-pixels, and may be referred to as a bank, a rib, a barrier wall, or the like. In the example shown in FIG. 2, the insulating layer 12 includes insulating layers (banks) 1211, 1212, 1213, 1214, 1221, and 1222. The insulating layers 1211, 1212, 1213, and 1214 extend in the second direction Y. The insulating layers 1211 to 1214 are arranged at intervals in the first direction X. The insulating layers 1211, 1212, 1213, and 1214 are arranged in the order described toward the distal part side of the arrow in the first direction X. The insulating layers 1221 and 1222 extend in the first direction X. The insulating layers 1221 and 1222 are arranged at an interval in the second direction Y. The insulating layers 1221 and 1222 are arranged in the order described toward the distal part side of the arrow in the second direction Y. The insulating layers 1211 to 1214 intersect the insulating layers 1221 and 1222. The insulating layer 12 has opening portions OP overlapping the lower electrode E1.

In the example shown in FIG. 2, the insulating layer 12 has an opening portion OP1 overlapping the lower electrode E11, an opening portion OP2 overlapping the lower electrode E12, and an opening portion OP3 overlapping the lower electrode E13. The opening portion OP1 corresponds to a region surrounded by the insulating layers 1211 and 1212 and the insulating layers 1221 and 1222. In other words, the central portion of the lower electrode E11 overlapping the opening portion OP1 is exposed from the insulating layer 12. The opening portion OP2 corresponds to a region surrounded by the insulating layers 1212 and 1213 and the insulating layers 1221 and 1222. In other words, the central portion of the lower electrode E12 overlapping the opening portion OP2 is exposed from the insulating layer 12. The opening portion OP3 corresponds to a region surrounded by the insulating layers 1213 and 1214 and the insulating layers 1221 and 1222. In other words, the central portion of the lower electrode E13 overlapping the opening portion OP3 is exposed from the insulating layer 12.

In the example shown in FIG. 2, the insulating layer 12 covers a peripheral portion of each of the lower electrodes E11 to E13. The insulating layer 1221 overlaps the end portion of the lower electrode E11, the end portion of the lower electrode E12, and the end portion of the lower electrode E13. The insulating layer 1222 overlaps the end portion of the lower electrode E11, the end portion of the lower electrode E12, and the end portion of the lower electrode E13. The insulating layer 1211 overlaps the end portion of the lower electrode E11. The insulating layer 1212 overlaps the end portion of the lower electrode E11 and the end portion of the lower electrode E12. The insulating layer 1213 overlaps the end portion of the lower electrode E12 and the end portion of the lower electrode E13. The insulating layer 1214 overlaps the end portion of the lower electrode E13.

The auxiliary line CAW overlaps the insulating layer 12. For example, the auxiliary line CAW is disposed in a lattice pattern so as to overlap the insulating layer 12 in planar view. For example, the auxiliary line CAW does not overlap the lower electrode E1 in planar view.

In the example shown in FIG. 2, the auxiliary line CAW includes auxiliary lines CAW11, CAW12, CAW13, CAW14, CAW21, and CAW22. The auxiliary lines CAW11, CAW12, CAW13, and CAW14 extend in the second direction Y. The auxiliary lines CAW11 to CAW14 are arranged at intervals in the first direction X. For example, the auxiliary lines CAW11, CAW12, CAW13, and CAW14 are arranged in the order described toward the distal part side of the arrow in the first direction X. The auxiliary lines CAW21 and CAW22 extend in the first direction X. The auxiliary lines CAW21 and CAW22 are arranged at an interval in the second direction Y. For example, the auxiliary lines CAW21 and CAW22 are arranged in the order described toward the distal part side of the arrow in the second direction Y. The auxiliary lines CAW11 to CAW14 intersect the auxiliary lines CAW21 and CAW22.

In the example shown in FIG. 2, the auxiliary line CAW11 overlaps the insulating layer 1211, the auxiliary line CAW12 overlaps the insulating layer 1212, the auxiliary line CAW13 overlaps the insulating layer 1213, and the auxiliary line CAW14 overlaps the insulating layer 1214. The auxiliary line CAW21 overlaps the insulating layer 1221, and the auxiliary line CAW22 overlaps the insulating layer 1222. The auxiliary lines CAW11 to CAW14 and the auxiliary lines CAW21 and CAW22 do not overlap the lower electrode E1.

In this case, the outer shape of the sub-pixel SP corresponds to, for example, the outer shape of the lower electrode E1. That is, the sub-pixel SP1, the sub-pixel SP2, and the sub-pixel SP3 that constitute one pixel PX are each formed in an approximately rectangular shape extending in the second direction Y and are arranged in the first direction X. Colors of light emitted from sub-pixels arranged adjacent to each other in the first direction X are different from each other. Incidentally, colors of light emitted from sub-pixels arranged adjacent to each other in the first direction X may be the same. The areas of the sub-pixel SP1, the sub-pixel SP2, and the sub-pixel SP3 may be the same or may be different from each other as described later. In addition, the outer shape of the sub-pixel may be defined by the outer shape of the light emission region of the display element.

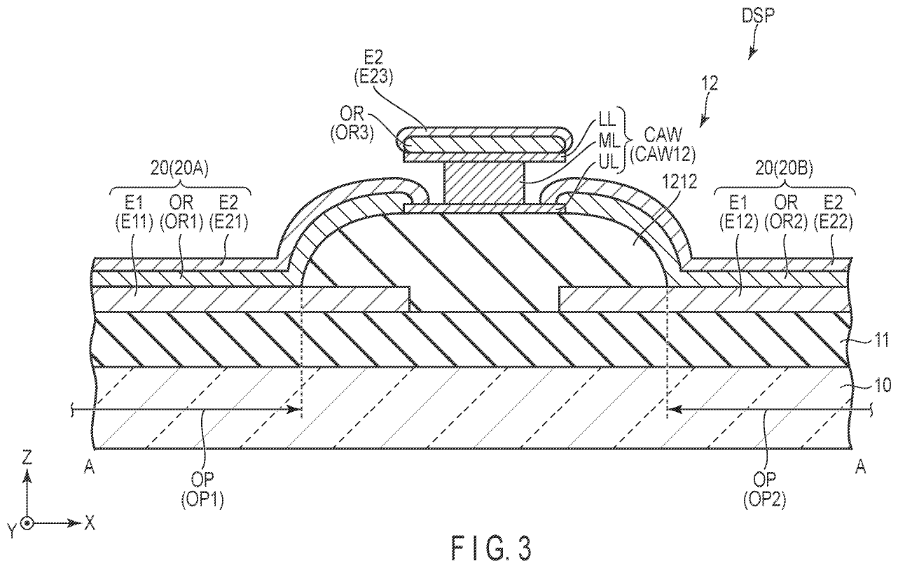

FIG. 3 is a cross-sectional view showing a configuration example of the display device DSP taken along line A-A shown in FIG. 2. Incidentally, FIG. 3 shows only the main portion of the display device DSP.

The display device DSP includes a substrate 10, an insulating layer 11, a lower electrode E1 (E11 and E12), an insulating layer 12 (1212), an organic layer OR (OR1, OR2, and OR3), and an upper electrode E2 (E21, E22, and E23) and an auxiliary line CAW (CAW12). The display device DSP includes a display element 20. The display element 20 (20A and 20B) includes a lower electrode E1 (E11 and E12), an organic layer OR (OR1 and OR2), and an upper electrode E2 (E21 and E22).

In the example shown in FIG. 3, the display element 20 includes display elements 20A and 20B. The display element 20A includes a lower electrode E11, an organic layer OR1, and an upper electrode E21. The display element 20B includes a lower electrode E12, an organic layer OR2, and an upper electrode E22.

The insulating layer 11 is disposed on the substrate 10. The insulating layer 11 corresponds to an underlayer of the display element 20, and is, for example, an organic insulating layer. Incidentally, the pixel switch 2 and the like of the pixel circuit 1 shown in FIG. 1 are disposed on the substrate 10 and covered with an insulating layer, for example, the insulating layer 11, but are not shown in this case. In the example shown in FIG. 3, the insulating layer 11 corresponds to an underlayer of the display elements 20A and 20B. Incidentally, the insulating layer 11 may be formed of a single-layer or formed of a plurality of layers. In addition, another layer may be disposed between the substrate 10 and the insulating layer 11.

The lower electrode E1 is disposed on the insulating layer 11. In the example shown in FIG. 3, the lower electrode E1 includes lower electrodes E11 and E12. The lower electrodes E11 and E12 are disposed on the insulating layer 11. The plurality of lower electrodes E1 are arranged at intervals in the first direction X. In the example shown in FIG. 3, the lower electrode E11 and the lower electrode E12 are disposed with a gap (alternatively an interval) in the first direction X. Although not shown, the lower electrode E1 may be electrically connected to the switching elements via a contact hole formed in the insulating layer 11. Although not shown, for example, the lower electrode E11 may be electrically connected to the switching elements via a contact hole formed in the insulating layer 11. Although not shown, for example, the lower electrode E12 may be electrically connected to the switching elements via a contact hole formed in the insulating layer 11. Incidentally, another layer may be disposed between the lower electrode E1 and the insulating layer 11.

The lower electrode E1 (E11 and E12) is, for example, a transparent electrode formed of a transparent conductive material such as indium tin oxide (ITO) or indium zinc oxide (IZO). Incidentally, the lower electrode E1 may be a metal electrode formed of a metal material such as silver or aluminum. In addition, the lower electrode E1 may be a stacked layer body of a transparent electrode and a metal electrode. For example, the lower electrode E1 may be configured as a single-layer, may be configured as a stacked layer body in which a transparent electrode, a metal electrode, and a transparent electrode are stacked in this order, or may be configured as a stacked layer body of three or more layers.

The insulating layer 12 is disposed on the insulating layer 11 and the lower electrode E1. The insulating layer 12 is, for example, an organic insulating layer. The insulating layer 12 has opening portions OP (OP1 and OP2). The opening portions OP are formed on the lower electrode E1. The opening portions OP are formed penetrating the insulating layer 12 to the lower electrode E1. In the example shown in FIG. 3, the insulating layer 12 includes an opening portion OP1, an opening portion OP2, and a bank 1212. The opening portion OP1 is formed on the lower electrode E11. The opening portion OP2 is formed on the lower electrode E12. The bank 1212 is located on the insulating layer 11, the end portion of the lower electrode E11, and the end portion of the lower electrode E12. The bank 1212 has, for example, a surface curved from the opening portion OP1 to a vertex portion of the bank 1212 and a surface curved from the opening portion OP2 to the vertex portion. The thickness of the bank 1212 is, for example, several μm, for example, 1.5 μm to 2.0 μm.

The organic layer OR is disposed on the lower electrode E1 and the insulating layer 12. In the example shown in FIG. 3, the organic layer OR includes organic layers OR1, OR2, and OR3. The organic layer OR1 is disposed on the lower electrode E11 corresponding to the opening portion OP1 and on the bank 1212. The organic layer OR1 is disposed on a surface curved from the lower electrode E11 corresponding to the opening portion OP1 to the vertex portion of the bank 1212. The organic layer OR2 is disposed on the lower electrode 512 corresponding to the opening portion OP2 and on the bank 1212. The organic layer OR2 is disposed on a surface curved from the lower electrode 512 corresponding to the opening portion OP2 to the vertex portion of the bank 1212. The organic layer OR3 is disposed on the auxiliary line CAW12 to be described later. The organic layers OR1 to OR3 are not in contact with each other. In other words, the organic layers OR1 to OR3 are divided. In other words, the organic layer OR1 is separated from the organic layers OR2 and OR3, the organic layer OR2 is separated from the organic layers OR3 and OR1, and the organic layer OR3 is separated from the organic layers OR1 and OR2. The organic layer OR1 is in contact with the auxiliary line CAW12 to be described later, for example, an end portion of the auxiliary line CAW12 on the side opposite to the distal part side of the arrow in the first direction X. Incidentally, the organic layer OR1 may not be in contact with the auxiliary line CAW12. The organic layer OR2 is in contact with the auxiliary line CAW12 to be described later, for example, the end portion of the auxiliary line CAW12 on the distal part side of the arrow in the first direction X. Incidentally, the organic layer OR2 may not be in contact with the auxiliary line CAW12.

The organic layer OR includes a light emitting layer that emits light with the magnitude of a current flowing by applying a predetermined voltage between the lower electrode E1 and the upper electrode E2. The organic layer OR includes at least one of a hole injection layer, a hole transport layer, an electron-injection layer, and an electron-transport layer in addition to the light emitting layer. For example, the organic layers OR1 to OR3 include light emitting layers of the same color. Incidentally, the organic layers OR1 to OR3 may include light emitting layers of different colors.

The upper electrode E2 is disposed on the organic layer OR. The upper electrode E2 covers the organic layer OR. In the example shown in FIG. 3, the upper electrode E2 includes upper electrodes E21, E22, and E23. The upper electrode E21 is disposed on the organic layer OR1. The upper electrode E21 covers the organic layer OR1. The upper electrode E22 is disposed on the organic layer OR2. The upper electrode E22 covers the organic layer OR2. The upper electrode E23 is disposed on the organic layer OR3. The upper electrode E23 covers the organic layer OR3. The upper electrode E21 is in contact with the auxiliary line CAW12 to be described later, for example, the end portion of the auxiliary line CAW12 on the side opposite to the distal part side of the arrow in the first direction X. The upper electrode E22 is in contact with the auxiliary line CAW12 to be described later, for example, the end portion of the auxiliary line CAW12 on the distal part side of the arrow in the first direction X. The upper electrode E23 is separated from the upper electrodes E21 and E22.

The upper electrode E2 is, for example, a transparent electrode formed of a transparent conductive material such as ITO or IZO. The upper electrode E2 is electrically connected to the feeder line FL located in the display region DA shown in FIG. 1. The upper electrode E2 is an electrode disposed in common for a plurality of sub-pixels, alternatively a plurality of display elements, and may be referred to as a common electrode, a counter-electrode, a cathode, or the like. Incidentally, the upper electrode E2 may be covered with a transparent protective layer (including at least one of an inorganic insulating layer and an organic insulating layer). The upper electrode E2 may be configured as a single-layer or a stacked layer body.

The auxiliary line CAW is disposed on the insulating layer 12. In the example shown in FIG. 3, the auxiliary line CAW includes the auxiliary line CAW12. The auxiliary line CAW12 is disposed on the bank 1212. The auxiliary line CAW12 is, for example, disposed on the vertex portion of the bank 1212.

The auxiliary line CAW is interposed between the two organic layers OR adjacent to each other. In other words, the auxiliary line CAW is interposed between the two upper electrodes E2 adjacent to each other. In the example shown in FIG. 3, the auxiliary line CAW12 is interposed between the organic layers OR1 and OR2. In other words, the auxiliary line CAW12 is interposed between the upper electrode E21 and the upper electrode E22.

The auxiliary line CAW separates (alternatively divides) the two organic layers OR adjacent to each other. The auxiliary line CAW separates (alternatively divides) the two upper electrodes E2 adjacent to each other and electrically connects the two upper electrodes E2 adjacent to each other to each other. In the example shown in FIG. 3, the auxiliary line CAW12 separates (alternatively divides) the organic layer OR1 and the organic layer OR2. The auxiliary line CAW12 separates (alternatively divides) the upper electrodes E21 and E22 adjacent to each other and electrically connects the upper electrodes E21 and E22 adjacent to each other to each other.

The auxiliary line CAW is a metal line, for example, a low-resistance metal line. The auxiliary line CAW can be used, for example, to assist a reduction in the resistance of a layer having high electric resistance and containing a transparent conductive material such as indium tin oxide (ITO) or indium zinc oxide (IZO).

The auxiliary line CAW is configured as a stacked layer body. Incidentally, the auxiliary line CAW may not be configured as a stacked layer body, and may be configured as a single-layer. The auxiliary line CAW is formed of a metal film of three layers, for example, layers of titanium (Ti), aluminum (Al), and titanium (Ti). In the example shown in FIG. 3, the auxiliary line CAW12 includes an upper layer LL, a middle layer ML, and a lower layer UL. The upper layer LL, the middle layer ML, and the lower layer UL are, for example, low-resistance metal lines. The upper layer LL is formed of, for example, titanium (Ti). The middle layer ML is formed of, for example, aluminum (Al). The lower layer UL is formed of, for example, titanium (Ti). Incidentally, in the auxiliary line CAW12, the upper layer LL and the middle layer ML may be a semiconductor, alternatively an insulator, and the lower layer UL may be a low-resistance metal line.

In the example shown in FIG. 3, the lower layer UL is, for example, disposed on the vertex portion of the bank 1212. In the auxiliary line CAW12, the middle layer ML is disposed on the lower layer UL, and the upper layer LL is disposed on the middle layer ML. In the auxiliary line CAW12, the middle layer ML is retracted to the central portion side, alternatively the inner side with respect to the lower layer UL and the upper layer LL. In other words, the width of the middle layer ML is smaller than the widths of the lower layer UL and the upper layer LL. In other words, the widths of the upper layer LL and the lower layer UL are longer than the width of the middle layer ML. The widths of the upper layer LL and the lower layer UL are equal. Incidentally, the widths of the upper layer LL and the lower layer UL may be different. In addition, the widths of the upper layer LL, the middle layer ML, and the lower layer UL may be the same.

In the example shown in FIG. 3, in the auxiliary line CAW12, the upper layer LL and the lower layer UL protrude more than the middle layer ML. In the auxiliary line CAW12, the upper layer LL has a function as an eave for the middle layer ML that shields the organic layer OR to prevent the organic layer OR from adhering to the middle layer ML. In the auxiliary line CAW12, the lower layer UL electrically connects the upper electrodes E21 and E22 to each other, and reduces the resistance of a layer having high electric resistance, for example, the upper electrode E2.

In the example shown in FIG. 3, the thickness of the auxiliary line CAW12 is equal to or larger than a thickness obtained by stacking the organic layer OR (OR1 and OR2) disposed on the bank 1212 and the upper electrode E2 (E 21 and E 22). The thickness of the auxiliary line CAW12 corresponds to, for example, a distance between the vertex portion of the bank 1212 and the organic layer OR3. The upper layer LL is separated from the upper electrodes E21 and E22. In other words, the upper layer LL is not in contact with the upper electrodes E21 and E22. The middle layer ML is separated from the upper electrodes E21 and E22. In other words, the middle layer ML is not in contact with the upper electrodes E21 and E22. The lower layer UL is in contact with the upper electrodes E21 and E22. In addition, the lower layer UL is in contact with the organic layers OR1 and OR2. Incidentally, the lower layer UL may not be in contact with the organic layers OR1 and OR2. In other words, the lower layer UL may be separated from the organic layers OR1 and OR2.

In the display element 20, a light emission region is formed by interposing the organic layer OR between the lower electrode E1 and the upper electrode E2. In the example shown in FIG. 3, in the display element 20A, a light emission region is formed by interposing the organic layer OR1 between the lower electrode E11 and the upper electrode E21. In the display element 20B, a light emission region is formed by interposing the organic layer OR2 between the lower electrode E12 and the upper electrode E22. Incidentally, since the organic layer OR3 is interposed between the auxiliary line CAW12 and the upper electrode E23 and is completely separated from the organic layer OR1 and the organic layer OR2, the organic layer OR3 hardly emits light, alternatively does not emit light. In addition, a part covering the bank 1212 in the organic layer OR1 is located between the bank 1212 and the upper electrode E21, and thus hardly emits light. Similarly, a part covering the bank 1212 in the organic layer OR2 is located between the bank 1212 and the upper electrode E22, and thus hardly emits light.

In the display device DSP, for example, the organic layer OR is formed by a vacuum vapor deposition method. In the example shown in FIG. 3, after the bank 1212 is formed, an organic material for forming the organic layers OR (OR1 to OR3) is vapor deposited. In a case where the organic material is vapor deposited, the organic layer OR is vapor deposited on the upper layer LL, and the organic layer OR is not attached to the middle layer ML due to the shadowing effect by the upper layer LL. The organic layer OR is attached to the lower layer UL, for example, an end portion of the lower layer UL. In the example shown in FIG. 3, the organic layer OR1 is in contact with the end portion of the lower layer UL on the side opposite to the distal part side of the arrow in the first direction X. Incidentally, the organic layer OR1 may not be in contact with the end portion of the lower layer UL on the side opposite to the distal part side of the arrow in the first direction X. The organic layer OR2 is in contact with the end portion of the lower layer UL on the distal part side of the arrow in the first direction X. Incidentally, the organic layer OR2 may not be in contact with the end portion of the lower layer UL on the distal part side of the arrow in the first direction X. The upper electrode E2 is formed by, for example, a sputtering method. When the upper electrode E2 is formed by the sputtering method, the upper electrode E2 is attached to the lower layer UL and electrically connected to the auxiliary line CAW. In the example shown in FIG. 3, the upper electrode E21 goes around to the inner side of the organic layer OR1 attached to the end portion of the lower layer UL on the side opposite to the distal part side of the arrow in the first direction X, and is attached to the lower layer UL and electrically connected to the lower layer UL of the auxiliary line CAW12. The upper electrode E22 goes around to the inner side of the organic layer OR2 attached to the end portion of the lower layer UL on the distal part side of the arrow in the first direction X, and is attached to the lower layer UL and electrically connected to the lower layer UL of the auxiliary line CAW12. For this reason, the upper electrodes E21 and E22 are electrically connected to each other via the lower layer UL.

In the example shown in FIG. 3, the auxiliary line CAW12 is formed by stacking and sputtering the upper layer LL, the middle layer ML, and the lower layer UL. The auxiliary line CAW12 formed by stacking and sputtering the upper layer LL, the middle layer ML, and the lower layer UL is patterned in a hot step and etched to obtain a three-layer film having a rectangular cross section. Thereafter, the middle layer (for example, aluminum) ML is selectively etched using an etching solution of weak alkali or aluminum, whereby the auxiliary line CAW12 in which the middle layer (for example, aluminum) ML is concave is obtained.

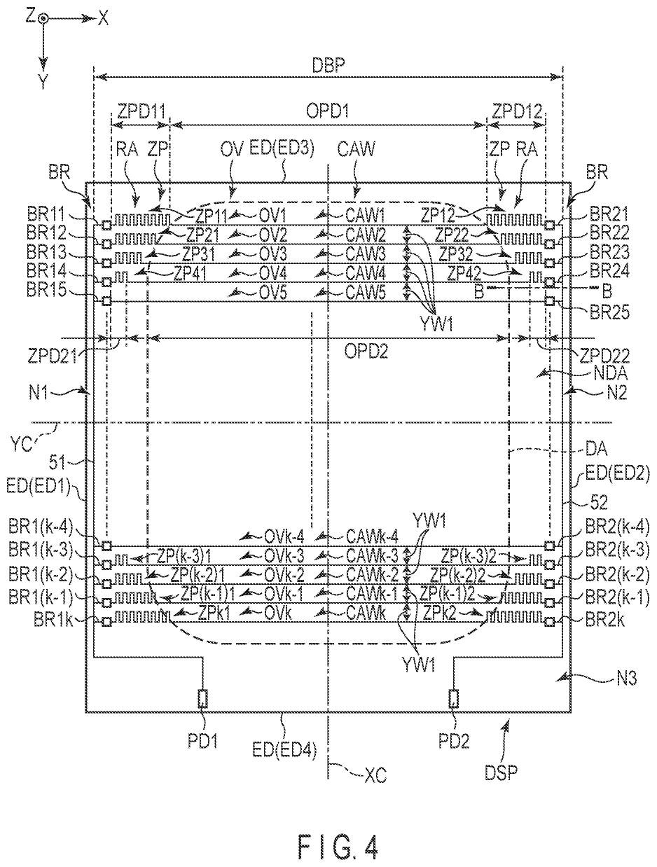

FIG. 4 is a plan view showing a configuration example of the auxiliary line CAW according to the embodiment. FIG. 4 shows only configurations necessary for description. FIG. 4 shows an axis XC passing through the center of the width of the display region DA in the first direction X and an axis YC passing through the center of the width of the display region DA in the second direction Y. FIG. 4 shows a range DBP from the power line 51 to the power line 52 in the first direction X.

In the example shown in FIG. 4, the plurality of peripheral lines BR extend in the first direction X and are arranged in the second direction Y in the non-display region NDA. The plurality of peripheral lines BR include peripheral lines BR11, BR12, BR13, BR14, BR15, . . . , BR1(k−4), BR1(k−3), BR1(k−2), BR1(k−1), and BR1k, and peripheral lines BR21, BR22, BR23, BR24, BR25, . . . , BR2(k−4), BR2(k−3), BR2(k−2), BR2(k−1), and BR2k.

In the example shown in FIG. 4, the plurality of peripheral lines BR11, BR12, BR13, BR14, BR15, . . . , BR1(k−4), BR1(k−3), BR1(k−2), BR1(k−1), and BR1k extend in the first direction X and are arranged in at interval the second direction Y from the edge portion ED3 side to the edge portion ED4 side in the order described in the first peripheral area N1. The plurality of peripheral lines BR11, BR12, BR13, BR14, BR15, . . . , BR1(k−4), BR1(k−3), BR1(k−2), BR1(k−1), and BR1k are arranged at regular intervals, for example, intervals YW1 in the second direction Y in the first peripheral area N1. Incidentally, the plurality of peripheral lines BR11, BR12, BR13, BR14, BR15, . . . , BR1(k−4), BR1(k−3), BR1(k−2), BR1(k−1), and BR1k may be arranged at different intervals in the second direction Y in the first peripheral area N1.

In the example shown in FIG. 4, the plurality of peripheral lines BR21, BR22, BR23, BR24, BR25, . . . , BR2(k−4), BR2(k−3), BR2(k−2), BR2(k−1), and BR2k extend in the first direction X and are arranged at interval in the second direction Y from the edge portion ED3 side to the edge portion ED4 side in the order described in the second peripheral area N2. The plurality of peripheral lines BR21, BR22, BR23, BR24, BR25, . . . , BR2 (k−4), BR2 (k−3), BR2 (k−2), BR2 (k−1), and BR2k are arranged at regular intervals, for example, intervals YW1 in the second direction Y in the second peripheral area N2. Incidentally, the plurality of peripheral lines BR21, BR22, BR23, BR24, BR25, . . . , BR2(k−4), BR2(k−3), BR2(k−2), BR2(k−1), and BR2k may be arranged at different intervals in the second direction Y in the second peripheral area N2.

In the example shown in FIG. 4, the peripheral lines BR11 and BR21 are opposed to each other in the first direction X and are disposed symmetrically with respect to the central axis XC. The peripheral lines BR12 and BR22 are opposed to each other in the first direction X and are disposed symmetrically with respect to the central axis XC. The peripheral lines BR13 and BR23 are opposed to each other in the first direction X and are disposed symmetrically with respect to the central axis XC. The peripheral lines BR14 and BR24 are opposed to each other in the first direction X and are disposed symmetrically with respect to the central axis XC. The peripheral lines BR15 and BR25 are opposed to each other in the first direction X and are disposed symmetrically with respect to the central axis XC.

In the example shown in FIG. 4, the peripheral lines BR1k and BR2k are opposed to each other in the first direction X and are disposed symmetrically with respect to the central axis XC. The peripheral lines BR1(k−1) and BR2(k−1) are opposed to each other in the first direction X and are disposed symmetrically with respect to the central axis XC. The peripheral lines BR1(k−2) and BR2(k−2) are opposed to each other in the first direction X and are disposed symmetrically with respect to the central axis XC. The peripheral lines BR1(k−3) and BR2(k−3) are opposed to each other in the first direction X and are disposed symmetrically with respect to the central axis XC. The peripheral lines BR1(k−4) and BR2(k−4) are opposed to each other in the first direction X and are disposed symmetrically with respect to the central axis XC.

In the example shown in FIG. 4, the plurality of auxiliary lines CAW extend from the display region DA to the non-display region NDA in the first direction X and are arranged at intervals in the second direction Y. The plurality of auxiliary lines CAW are connected to the plurality of peripheral lines BR. In the non-display region NDA, the plurality of auxiliary lines CAW include a resistance adjustment portion RA that adjusts the resistance of the auxiliary lines CAW so as to offset a high and low distribution of the resistance of the upper electrode E2 in the display region DA, alternatively to make the voltage gradient of the upper electrode E2 in the display region DA constant. For example, in the non-display region NDA, the plurality of auxiliary lines CAW include a zigzag portion ZP (alternatively, a narrow portion where the widths of the auxiliary lines CAW are smaller than the widths of parts of the auxiliary lines CAW overlapping the display region DA) formed in a zigzag shape described later as the resistance adjustment portion RA. For example, the resistance adjustment portion RA increases the resistance of the auxiliary lines CAW in the non-display region NDA. Incidentally, the resistance adjustment portion RA may be configured to reduce the resistance of the auxiliary lines CAW in the non-display region NDA.

The range (for example, length) of the resistance adjustment portion RA changes according to, for example, the range of a portion (hereinafter, it may be referred to as an overlapping portion) OV of the auxiliary lines CAW overlapping the display region DA and the pixels PX, alternatively either the display region DA or the pixels PX. In other words, the range (for example, length) of the resistance adjustment portion RA changes according to the range of the auxiliary lines CAW overlapping the display region DA.

In addition, the range (for example, length) of the resistance adjustment portion RA changes according to the number of pixels PX that the auxiliary lines CAW overlap. For example, in a region where a range overlapping the display region DA is large and the number of pixels PX (disposed in the first direction X) is large, the resistance of the upper electrode E2 is relatively high, and in a region where a range overlapping the display region DA is small and the number of pixels PX (disposed in the first direction X) is small, the resistance of the upper electrode E2 can be relatively low.

For example, when the range (for example, length) of the overlapping portion OV of the auxiliary line CAW disposed on the edge portion side in the second direction Y of the corner portion of the display region DA formed in the round shape is smaller than the range of the overlapping portion OV of the auxiliary line CAW disposed on the central axis YC side in the second direction Y of the corner portion of the display region DA, the range (for example, length) of the resistance adjustment portion RA of the auxiliary line CAW disposed on the edge portion side in the second direction Y of the corner portion of the display region DA is larger than the range of the resistance adjustment portion RA of the auxiliary line CAW disposed on the central axis YC side in the second direction Y of the corner portion of the display region DA.

In the example shown in FIG. 4, the plurality of auxiliary lines CAW include auxiliary lines CAW1, CAW2, CAW3, CAW4, CAW5, . . . , CAWk−4, CAWk−3, CAWk−2, CAWk−1, and CAWk.

In the example shown in FIG. 4, the plurality of auxiliary lines CAW1, CAW2, CAW3, CAW4, CAW5, . . . , CAWk−4, CAWk−3, CAWk−2, CAWk−1, and CAWk extend in the first direction X from the display region DA to the first peripheral area N1 and the second peripheral area N2, and are arranged at intervals in the second direction Y from the edge portion ED3 side to the edge portion ED4 side in the order described. The plurality of auxiliary lines CAW1, CAW2, CAW3, CAW4, CAW5, . . . , CAWk−4, CAWk−3, CAWk−2, CAWk−1, and CAWk are arranged at regular intervals, for example, intervals YW1 in the second direction Y. Incidentally, the plurality of auxiliary lines CAW1, CAW2, CAW3, CAW4, CAW5, . . . , CAWk−4, CAWk−3, CAWk−2, CAWk−1, and CAWk may be arranged at different intervals in the second direction Y.

In the example shown in FIG. 4, the auxiliary line CAW1 includes an overlapping portion OV1, a zigzag portion ZP11 disposed in the first peripheral area N1, and a zigzag portion ZP12 disposed in the second peripheral area N2. The auxiliary line CAW1 is electrically connected to the peripheral lines BR11 and BR21. The auxiliary line CAW2 includes an overlapping portion OV2, a zigzag portion ZP21 disposed in the first peripheral area N1, and a zigzag portion ZP22 disposed in the second peripheral area N2. The auxiliary line CAW2 is electrically connected to the peripheral lines BR12 and BR22. The auxiliary line CAW3 includes an overlapping portion OV3, a zigzag portion ZP31 disposed in the first peripheral area N1, and a zigzag portion ZP32 disposed in the second peripheral area N2. The auxiliary line CAW3 is electrically connected to the peripheral lines BR13 and BR23. The auxiliary line CAW4 includes an overlapping portion OV4, a zigzag portion ZP41 disposed in the first peripheral area N1, and a zigzag portion ZP42 disposed in the second peripheral area N2. The auxiliary line CAW4 is electrically connected to the peripheral lines BR14 and BR24. The auxiliary line CAW5 overlaps an overlapping portion OV5. The auxiliary line CAW5 is electrically connected to the peripheral lines BR15 and BR25. Incidentally, the auxiliary lines CAW may include the peripheral lines BR.

In the example shown in FIG. 4, the auxiliary line CAWk−4 includes an overlapping portion OVk−4. The auxiliary line CAWk−4 is electrically connected to the peripheral lines BR1(k−4) and BR2(k−4). The auxiliary line CAWk−3 includes an overlapping portion OVk−3, a zigzag portion ZP(k−3)1 disposed in the first peripheral area N1, and a zigzag portion ZP(k−3)2 disposed in the second peripheral area N2. The auxiliary line CAWk−3 is electrically connected to the peripheral lines BR1(k−3) and BR2(k−3). The auxiliary line CAWk−2 includes an overlapping portion OVk−2, a zigzag portion ZP(k−2)1 disposed in the first peripheral area N1, and a zigzag portion ZP(k−2)2 disposed in the second peripheral area N2. The auxiliary line CAWk−2 is electrically connected to the peripheral lines BR1(k−2) and BR2(k−2). The auxiliary line CAWk−1 includes an overlapping portion OVk−1, a zigzag portion ZP(k−1)1 disposed in the first peripheral area N1, and a zigzag portion ZP(k−1)2 disposed in the second peripheral area N2. The auxiliary line CAWk−1 is electrically connected to the peripheral lines BR1(k−1) and BR2(k−1). The auxiliary line CAWk includes an overlapping portion OVk, a zigzag portion ZPk1 disposed in the first peripheral area N1, and a zigzag portion ZPk2 disposed in the second peripheral area N2. The auxiliary line CAWk is electrically connected to the peripheral lines BR1k and BR2k.

The lengths of the overlapping portions OV1, OV2, OV3, OV4, and OV5 are shorter in the order described. The lengths of the zigzag portions ZP11, ZP21, ZP31, and ZP41 are longer in the order described. The lengths of the zigzag portions ZP12, ZP22, ZP32, and ZP42 are longer in the order described. For example, the lengths of the zigzag portions ZP11 and ZP12 are equal. Incidentally, for example, the lengths of the zigzag portions ZP11 and ZP12 may be different. For example, the lengths of the zigzag portions ZP21 and ZP22 are equal. Incidentally, for example, the lengths of the zigzag portions ZP21 and ZP22 may be different. For example, the lengths of the zigzag portions ZP31 and ZP32 are equal. Incidentally, for example, the lengths of the zigzag portions ZP31 and ZP32 may be different. For example, the lengths of the zigzag portions ZP41 and ZP42 are equal. Incidentally, for example, the lengths of the zigzag portions ZP41 and ZP42 may be different.

For example, a length OPD1 of the overlapping portion OV1 is shorter than a length OPD2 of the overlapping portion OV4. A length ZPD11 of the zigzag portion ZP11 is longer than a length ZPD21 of the zigzag portion ZP41. A length ZPD12 of the zigzag portion ZP12 is longer than a length ZPD22 of the zigzag portion ZP42. For example, the length ZPD11 of the zigzag portion ZP11 is the same as the length ZPD12 of the zigzag portion ZP12. For example, the length ZPD21 of the zigzag portion ZP41 is the same as the length ZPD22 of the zigzag portion ZP42. For example, the voltage in the range DBP from the peripheral line BR11 to the peripheral line BR21 via the auxiliary line CAW1 is equal to the voltage in the range DBP from the peripheral line BR14 to the peripheral line BR24 via the auxiliary line CAW4.

In addition, for example, the voltage in the range DBP from the peripheral line BR11 to the peripheral line BR21 via the auxiliary line CAW1, the voltage in the range DBP from the peripheral line BR12 to the peripheral line BR22 via the auxiliary line CAW2, the voltage in the range DBP from the peripheral line BR13 to the peripheral line BR23 via the auxiliary line CAW3, the voltage in the range DBP from the peripheral line BR14 to the peripheral line BR24 via the auxiliary line CAW4, and the voltage in the range DBP from the peripheral line BR15 to the peripheral line BR25 via the auxiliary line CAW5 are equal.

The lengths of the overlapping portions OVk−4, OVk−3, OVk−2, OVk−1, and OVk are shorter in the order described. The lengths of the zigzag portions ZP(k−3)1, ZP(k−2)1, ZP(k−1)1, and ZPk1 are longer in the order described. The lengths of the zigzag portions ZP(k−3)2, ZP(k−2)2, ZP(k−1)2, and ZPk2 are longer in the order described. For example, the lengths of the zigzag portions ZP(k−3)1 and ZP(k−3)2 are equal. Incidentally, for example, the lengths of the zigzag portions ZP(k−3)1 and ZP(k−3)2 may be different. For example, the lengths of the zigzag portions ZP(k−2)1 and ZP(k−2)2 are equal. Incidentally, for example, the lengths of the zigzag portions ZP(k−2)1 and ZP(k−2)2 may be different. For example, the lengths of the zigzag portions ZP(k−1)1 and ZP(k−1)2 are equal. Incidentally, for example, the lengths of the zigzag portions ZP(k−1)1 and ZP(k−1)2 may be different. For example, the lengths of the zigzag portions ZPk1 and ZPk2 are equal. Incidentally, for example, the lengths of the zigzag portions ZPk1 and ZPk2 may be different.

For example, the length of the overlapping portion OVk and the length of the overlapping portion OV1 are equal. Incidentally, the length of the overlapping portion OVk and the length of the overlapping portion OV1 may be different. The length of the overlapping portion OVk−1 and the length of the overlapping portion OV2 are equal. Incidentally, the length of the overlapping portion OVk−1 and the length of the overlapping portion OV2 may be different. The length of the overlapping portion OVk−2 and the length of the overlapping portion OV3 are equal. Incidentally, the length of the overlapping portion OVk−2 and the length of the overlapping portion OV3 may be different. The length of the overlapping portion OVk−3 and the length of the overlapping portion OV4 are equal. Incidentally, the length of the overlapping portion OVk−3 and the length of the overlapping portion OV4 may be different. The length of the overlapping portion OVk−4 and the length of the overlapping portion OV5 are equal. Incidentally, the length of the overlapping portion OVk−4 and the length of the overlapping portion OV5 may be different.

For example, the voltage in the range DBP from the peripheral line BR1k to the peripheral line BR2k via the auxiliary line CAWk, the voltage in the range DBP from the peripheral line BR1(k−1) to the peripheral line BR2(k−1) via the auxiliary line CAWk−1, the voltage in the range DBP from the peripheral line BR1(k−2) to the peripheral line BR2(k−2) via the auxiliary line CAWk−2, the voltage in the range DBP from the peripheral line BR1(k−3) to the peripheral line BR2(k−3) via the auxiliary line CAWk−3, and the voltage in the range DBP from the peripheral line BR1(k−4) to the peripheral line BR2(k−4) via the auxiliary line CAWk−4 are equal.

For example, the voltage in the range DBP from the peripheral line BR11 to the peripheral line BR21, the voltage in the range DBP from the peripheral line BR12 to the peripheral line BR22, the voltage in the range DBP from the peripheral line BR13 to the peripheral line BR23, the voltage in the range DBP from the peripheral line BR14 to the peripheral line BR24, the voltage in the range DBP from the peripheral line BR15 to the peripheral line BR25, . . . , the voltage in the range DBP from the peripheral line BR1(k−4) to the peripheral line BR2(k−4), the voltage in the range DBP from the peripheral line BR1(k−3) to the peripheral line BR2(k−3), the voltage in the range DBP from the peripheral line BR1(k−2) to the peripheral line BR2(k−2), the voltage in the range DBP from the peripheral line BR1(k−1) to the peripheral line BR2(k−1), and the voltage in the range DBP from the peripheral line BR1k to the peripheral line BR2k are equal.

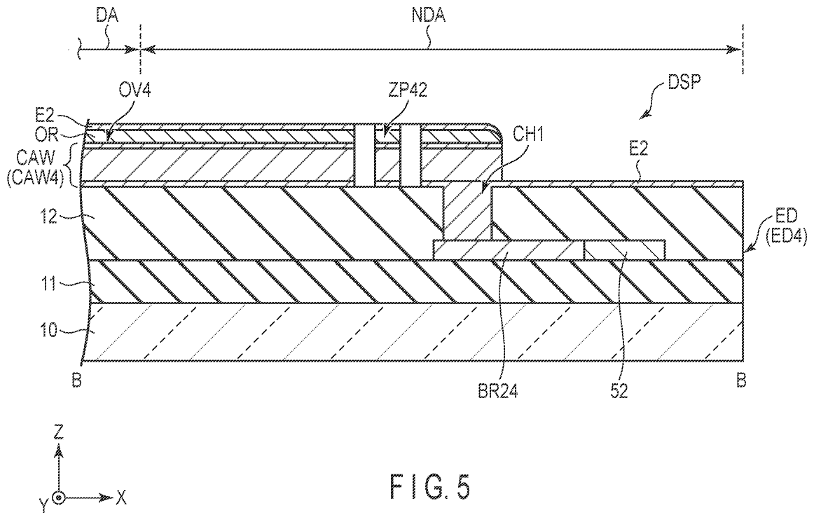

FIG. 5 is a cross-sectional view of the display device DSP taken along line B-B shown in FIG. 4.

In the example shown in FIG. 5, the peripheral line BR24 and the power line 52 are located on the insulating layer 11. The insulating layer 12 covers the peripheral line BR24 and the power line 52. The auxiliary line CAW (CAW4) is located on the insulating layer 12 and connected to the peripheral line BR24 through a contact hole CH1 formed in the insulating layer 12. The organic layer OR (OR3) is disposed on the auxiliary line CAW. Incidentally, the organic layer OR (OR3) may not be disposed on the auxiliary line CAW in the non-display region NDA. The upper electrode E2 is disposed on the organic layer OR (OR3) located on the auxiliary line CAW. In addition, the upper electrode E2 is located on the insulating layer 12 on which the auxiliary line CAW is not disposed in the non-display region NDA.

According to the present embodiment, the display device DSP includes the plurality of pixels PX, the insulating layer 12, the plurality of auxiliary lines CAW disposed on the insulating layer 12, the power lines 51 and 52 disposed in the non-display region NDA, and the plurality of peripheral lines BR connected to the power lines 51 and 52. The display device DSP has the display region DA and the non-display region NDA present around the display region DA. The display region DA has the round shape in which the length of the display region DA in the second direction Y is longer than the length of the display region DA in the first direction X and the corner portions are rounded. In the display device DSP, in the display region DA, the number of pixels PX disposed in the first direction X at each of the corner portions is smaller than the number of pixels PX disposed in the first direction X at the central portion in the second direction Y. The length of the overlapping portion OV of at least one auxiliary line CAW on the end portion side in the second direction Y of the display region DA is shorter than the length of the overlapping portion OV of at least one auxiliary line CAW on the central portion side in the second direction Y of the display region DA. The length of the resistance adjustment portion RA of at least one auxiliary line CAW on the end portion side in the second direction Y of the display region DA is longer than the length of the resistance adjustment portion RA of at least one auxiliary line CAW on the central portion side in the second direction Y of the display region DA. The voltage of at least one auxiliary line CAW on the end portion side in the second direction Y of the display region DA is equal to the voltage of at least one auxiliary line CAW on the central portion side in the second direction Y of the display region DA. For this reason, the display device DSP can uniformly apply a voltage to the plurality of pixels PX in the display region DA. Therefore, the display device DSP can improve the display quality.

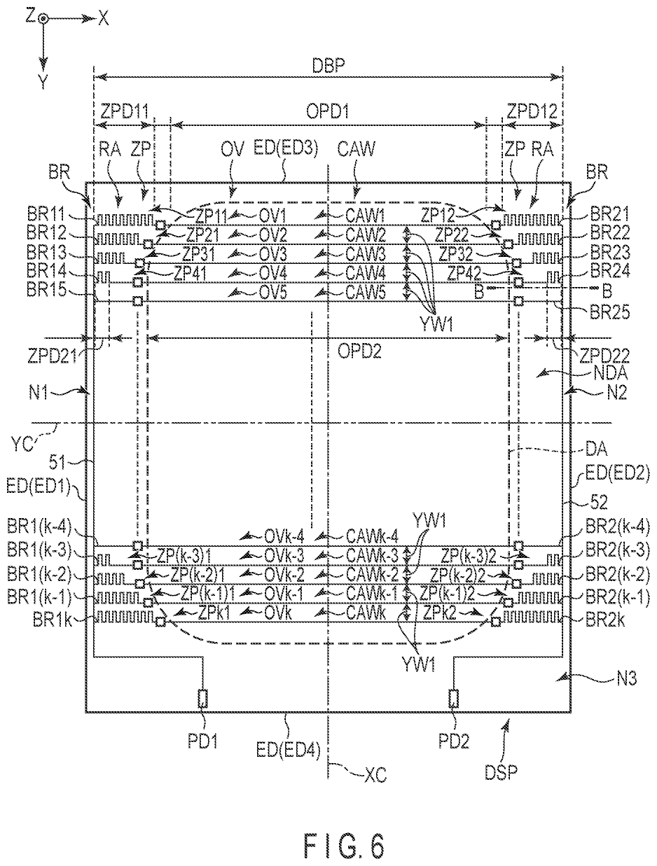

Next, modified examples of the present embodiment will be described with reference to FIGS. 6 to 11. In the modified examples of the present embodiment described below, the same parts as those described above are denoted by the same reference signs, detailed description thereof is omitted, and parts different from those described above will be mainly described in detail. Incidentally, in the other modified examples, the same effects as those of the above-described embodiment can be obtained.

### Modified Example 1

A display device DSP according to Modified Example 1 is different from the display device DSP according to the above-described embodiment in the configuration of the auxiliary lines CAW and the peripheral lines BR.

FIG. 6 is a plan view showing a configuration example of a peripheral line BR according to Modified Example 1. FIG. 6 shows only configurations necessary for description.

In the example shown in FIG. 6, some of a plurality of peripheral lines BR include resistance adjustment portions RA in the non-display region NDA. For example, some of the plurality of peripheral lines BR have zigzag portions ZP (alternatively, narrow portions) as the resistance adjustment portions RA in the non-display region NDA.

For example, when the range (for example, length) of the overlapping portion OV of the auxiliary line CAW disposed on the edge portion side in the second direction Y of the corner portion of the display region DA formed in the round shape is smaller than the range of the overlapping portion OV of the auxiliary line CAW disposed on the central axis YC side in the second direction Y of the corner portion of the display region DA, the range (for example, length) of the resistance adjustment portion RA of the peripheral line BR connected to the auxiliary line CAW disposed on the edge portion side in the second direction Y of the corner portion of the display region DA is larger than the range of the resistance adjustment portion RA of the peripheral line BR connected to the auxiliary line CAW disposed on the central axis YC side in the second direction Y of the corner portion of the display region DA.

In the example shown in FIG. 6, the peripheral line BR11 has a zigzag portion ZP11 disposed in the first peripheral area N1. The peripheral line BR21 has a zigzag portion ZP12 disposed in the second peripheral area N2. The peripheral line BR12 has a zigzag portion ZP21 disposed in the first peripheral area N1. The peripheral line BR22 has a zigzag portion ZP22 disposed in the second peripheral area N2.

The peripheral line BR13 has a zigzag portion ZP31 disposed in the first peripheral area N1. The peripheral line BR23 has a zigzag portion ZP32 disposed in the second peripheral area N2. The peripheral line BR14 has a zigzag portion ZP41 disposed in the first peripheral area N1. The peripheral line BR24 has a zigzag portion ZP42 disposed in the second peripheral area N2.

In the example shown in FIG. 6, the peripheral line BR1(k−3) has a zigzag portion ZP(k−3)1 disposed in the first peripheral area N1. The peripheral line BR2(k−3) has a zigzag portion ZP(k−3)2 disposed in the second peripheral area N2. The peripheral line BR1(k−2) has a zigzag portion ZP(k−2)1 disposed in the first peripheral area N1. The peripheral line BR2(k−2) has a zigzag portion ZP(k−2)2 disposed in the second peripheral area N2. The peripheral line BR1(k−1) has a zigzag portion ZP(k−1)1 disposed in the first peripheral area N1. The peripheral line BR2(k−1) has a zigzag portion ZP(k−1)2 disposed in the second peripheral area N2. The peripheral line BR1k has a zigzag portion ZPk1 disposed in the first peripheral area N1. The peripheral line BR2k has a zigzag portion ZPk2 disposed in the second peripheral area N2.

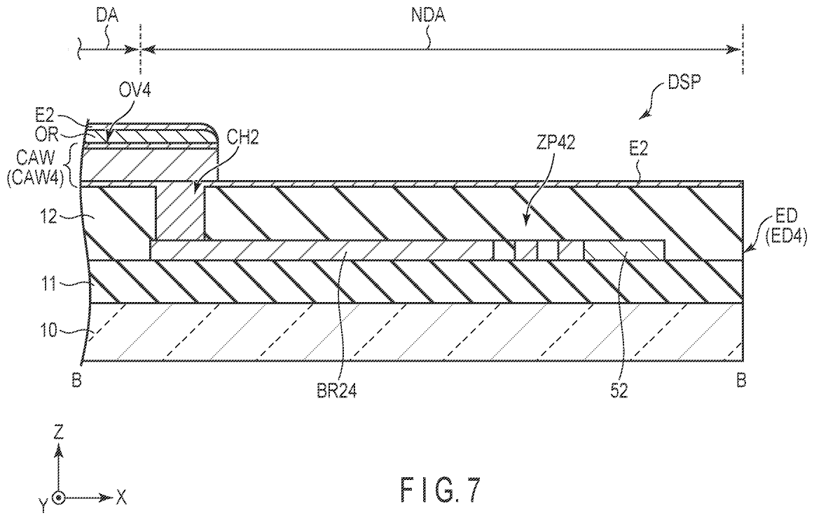

FIG. 7 is a cross-sectional view of the display device DSP taken along line B-B shown in FIG. 6.

In the example shown in FIG. 7, the insulating layer 12 covers the peripheral line BR24 and the power line 52. The auxiliary line CAW (CAW4) is located on the insulating layer 12 and connected to the peripheral line BR24 through a contact hole CH2 formed in the insulating layer 12. The upper electrode E2 is located on the insulating layer 12 on which the auxiliary line CAW is not disposed in the non-display region NDA.

For this reason, the display device DSP according to Modified Example 1 can obtain the same effects as those of the display device DSP according to the above-described embodiment.

### Modified Example 2

A display device DSP according to Modified Example 2 is different from the display device DSP according to the above-described embodiment and the display device DSP according to the above-described modified example in the configuration of the display region DA.

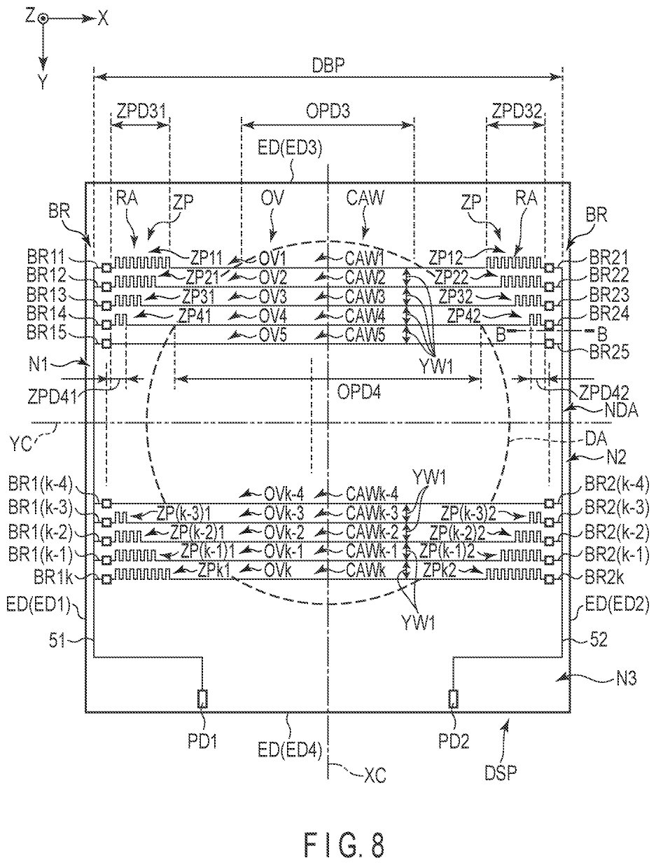

FIG. 8 is a plan view showing a configuration example of a display region DA according to Modified Example 2. Incidentally, FIG. 8 shows only the main portion of the display device DSP.

The display region DA has a round shape. Incidentally, the display region DA may have a shape other than the round shape.

In the example shown in FIG. 8, a plurality of peripheral lines BR include peripheral lines BR11, BR12, BR13, BR14, . . . , BR1(k−3), BR1(k−2), BR1(k−1), and BR1k, and peripheral line BR21, BR22, BR23, BR24, . . . , BR2(k−3), BR2(k−2), BR2(k−1), and BR2k.

In the example shown in FIG. 8, the plurality of peripheral lines BR11, BR12, BR13, BR14, . . . , BR1(k−3), BR1(k−2), BR1(k−1), and BR1k extend in the first direction X and are arranged at intervals in the second direction Y from the edge portion ED3 side to the edge portion ED4 side in the order described in the first peripheral area N1. The plurality of peripheral lines BR11, BR12, BR13, BR14, . . . , BR1(k−3), BR1(k−2), BR1(k−1), and BR1k are arranged at regular intervals, for example, intervals YW1 in the second direction Y in the first peripheral area N1. Incidentally, the plurality of peripheral lines BR11, BR12, BR13, BR14, . . . , BR1(k−3), BR1(k−2), BR1(k−1), and BR1k may be arranged at different intervals in the second direction Y in the first peripheral area N1.

In the example shown in FIG. 8, the plurality of peripheral lines BR21, BR22, BR23, BR24, . . . , BR2(k−3), BR2(k−2), BR2(k−1), and BR2k extend in the first direction X and are arranged at intervals in the second direction Y from the edge portion ED3 side to the edge portion ED4 side in the order described in the second peripheral area N2. The plurality of peripheral lines BR21, BR22, BR23, BR24, . . . , BR2(k−3), BR2(k−2), BR2(k−1), and BR2k are arranged at regular intervals, for example, intervals YW1 in the second direction Y in the second peripheral area N2. Incidentally, the plurality of peripheral lines BR21, BR22, BR23, BR24, . . . , BR2(k−3), BR2(k−2), BR2(k−1), and BR2k may be arranged at different intervals in the second direction Y in the second peripheral area N2.

In the example shown in FIG. 8, the peripheral lines BR11 and BR21 are opposed to each other in the first direction X and are disposed symmetrically with respect to the central axis XC. The peripheral lines BR12 and BR22 are opposed to each other in the first direction X and are disposed symmetrically with respect to the central axis XC. The peripheral lines BR13 and BR23 are opposed to each other in the first direction X and are disposed symmetrically with respect to the central axis XC. The peripheral lines BR14 and BR24 are opposed to each other in the first direction X and are disposed symmetrically with respect to the central axis XC.

In the example shown in FIG. 8, the peripheral lines BR1k and BR2k are opposed to each other in the first direction X and are disposed symmetrically with respect to the central axis XC. The peripheral lines BR1(k−1) and BR2(k−1) are opposed to each other in the first direction X and are disposed symmetrically with respect to the central axis XC. The peripheral lines BR1(k−2) and BR2(k−2) are opposed to each other in the first direction X and are disposed symmetrically with respect to the central axis XC. The peripheral lines BR1(k−3) and BR2(k−3) are opposed to each other in the first direction X and are disposed symmetrically with respect to the central axis XC.

In the example shown in FIG. 8, the plurality of auxiliary lines CAW include auxiliary lines CAW1, CAW2, CAW3, CAW4, . . . , CAWk−3, CAWk−2, CAWk−1, and CAWk. The plurality of auxiliary lines CAW1, CAW2, CAW3, CAW4, . . . , CAWk−3, CAWk−2, CAWk−1, and CAWk extend in the first direction X from the display region DA to the first peripheral area N1 and the second peripheral area N2 and are arranged at intervals in the second direction Y from the edge portion ED3 side to the edge portion ED4 side in the order described. The plurality of auxiliary lines CAW1, CAW2, CAW3, CAW4, . . . , CAWk−3, CAWk−2, CAWk−1, and CAWk are arranged at regular intervals, for example, intervals YW1 in the second direction Y. Incidentally, the plurality of auxiliary lines CAW1, CAW2, CAW3, CAW4, . . . , CAWk−3, CAWk−2, CAWk−1, and CAWk may be arranged at different intervals in the second direction Y.

For example, a length OPD3 of the overlapping portion OV1 is shorter than a length OPD4 of the overlapping portion OV4. A length ZPD31 of the zigzag portion ZP11 is longer than a length ZPD41 of the zigzag portion ZP41. A length ZPD32 of the zigzag portion ZP12 is longer than a length ZPD42 of the zigzag portion ZP42. For example, the length ZPD31 of the zigzag portion ZP11 is the same as the length ZPD32 of the zigzag portion ZP12. For example, the length ZPD41 of the zigzag portion ZP41 is the same as the length ZPD42 of the zigzag portion ZP42.

For example, the voltage in the range DBP from the peripheral line BR11 to the peripheral line BR21, the voltage in the range DBP from the peripheral line BR12 to the peripheral line BR22, the voltage in the range DBP from the peripheral line BR13 to the peripheral line BR23, the voltage in the range DBP from the peripheral line BR14 to the peripheral line BR24, . . . , the voltage in the range DBP from the peripheral line BR1(k−3) to the peripheral line BR2(k−3), the voltage in the range DBP from the peripheral line BR1(k−2) to the peripheral line BR2(k−2), the voltage in the range DBP from the peripheral line BR1(k−1) to the peripheral line BR2(k−1), and the voltage in the range DBP from the peripheral line BR1k to the peripheral line BR2k are equal.

For this reason, the display device DSP according to Modified Example 2 can obtain the same effects as those of the display device DSP according to the above-described embodiment and the display device DSP according to the above-described modified example.

### Modified Example 3

A display device DSP according to Modified Example 3 is different from the display device DSP according to the above-described embodiment and the display devices DSP according to the above-described modified examples in the configuration of the auxiliary lines CAW and the peripheral lines BR.

In the display device DSP according to Modified Example 3, the interval in the second direction Y of a plurality of auxiliary lines CAW connected to the power lines 51 and 52 among the plurality of auxiliary lines CAW disposed in a region in which a range overlapping the display region DA (alternatively the pixels PX) is large is smaller than the interval in the second direction Y of a plurality of auxiliary lines CAW connected to the power lines 51 and 52 among the plurality of auxiliary lines CAW disposed in a region in which a range overlapping the display region DA (alternatively the pixels PX) is small. In other words, in the display device DSP, the interval in the second direction Y of the plurality of auxiliary lines CAW connected to the power lines 51 and 52 among the plurality of auxiliary lines CAW disposed in the region in which the range overlapping the display region DA is small is larger than the interval in the second direction Y of the plurality of auxiliary lines CAW connected to the power lines 51 and 52 among the plurality of auxiliary lines CAW disposed in the region in which the range overlapping the display region DA is large.

For example, in the display device DSP, the density of the connections of the plurality of auxiliary lines CAW disposed in the region in which the range overlapping the display region DA (alternatively the pixels PX) is large to the power lines 51 and 52 is higher than the density of the connections of the plurality of auxiliary lines CAW disposed in the region in which the range overlapping the display region DA (alternatively the pixels PX) is small to the power lines 51 and 52. In other words, in the display device DSP, the density of the connections of the plurality of auxiliary lines CAW disposed in the region in which the range overlapping the display region DA is small to the power lines 51 and 52 is lower than the density of the connections of the plurality of auxiliary lines CAW disposed in the region in which the range overlapping the display region DA is large to the power lines 51 and 52.

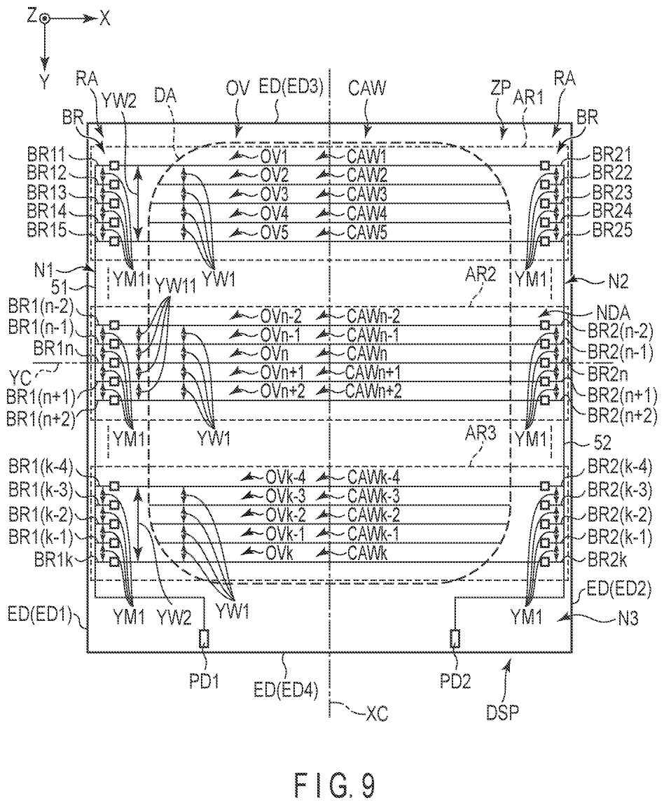

FIG. 9 is a plan view showing a configuration example of an auxiliary line CAW according to Modified Example 3.

In the example shown in FIG. 9, the plurality of peripheral lines BR include peripheral lines BR11, BR12, BR13, BR14, BR15, . . . , BR1(n−2), BR1(n−1), BR1n, BR1(n+1), BR1(n+2), . . . , BR1(k−4), BR1(k−3), BR1(k−2), BR1(k−1), and BR1k, and peripheral lines BR21, BR22, BR23, BR24, BR25, . . . , BR2(n−2), BR2(n−1), BR2n, BR2(n+1) BR2(n+2), . . . , BR2(k−4), BR2(k−3), BR2(k−2), BR2(k−1), and BR2k.

In the example shown in FIG. 9, the plurality of peripheral lines BR11, BR12, BR13, BR14, BR15, . . . , BR1(n−2), BR1(n−1), BR1n, BR1(n+1), BR1(n+2), . . . , BR1(k−4), BR1(k−3), BR1(k−2), BR1(k−1), and BR1k extend in the first direction X and are arranged at interval in the second direction Y from the edge portion ED3 side to the edge portion ED4 side in the order described in the first peripheral area N1. The plurality of peripheral lines BR11, BR12, BR13, BR14, BR15, . . . , BR1(n−2), BR1(n−1), BR1n, BR1(n+1), BR1(n+2), . . . , BR1(k−4), BR1(k−3), BR1(k−2), BR1(k−1), and BR1k are arranged at regular intervals, for example, intervals YM1 in the second direction Y in the first peripheral area N1.

In the example shown in FIG. 9, the plurality of peripheral lines BR21, BR22, BR23, BR24, BR25, . . . , BR2(n−2), BR2(n−1), BR2n, BR2(n+1), BR2(n+2), . . . , BR2(k−4), BR2(k−3), BR2(k−2), BR2(k−1), and BR2k extend in the first direction X and are arranged at interval in the second direction Y from the edge portion ED3 side to the edge portion ED4 side in the order described in the second peripheral area N2. The plurality of peripheral lines BR21, BR22, BR23, BR24, BR25, . . . , BR2(n−2), BR2(n−1), BR2n, BR2(n+1), BR2(n+2), . . . , BR2(k−4), BR2(k−3), BR2(k−2), BR2(k−1), and BR2k are arranged at regular intervals, for example, intervals YM1 in the second direction Y in the second peripheral area N2.

In the example shown in FIG. 9, the peripheral lines BR1(n−2) and BR2(n−2) are opposed to each other in the first direction X and are disposed symmetrically with respect to the central axis XC. The peripheral lines BR1(n−1) and BR2(n−1) are opposed to each other in the first direction X and are disposed symmetrically with respect to the central axis XC. The peripheral lines BR1n and BR2n are opposed to each other in the first direction X and are disposed symmetrically with respect to the central axis XC. The peripheral lines BR1(n+1) and BR2(n+1) are opposed to each other in the first direction X and are disposed symmetrically with respect to the central axis XC. The peripheral lines BR1(n+2) and BR2(n+2) are opposed to each other in the first direction X and are disposed symmetrically with respect to the central axis XC.

For example, when the range of the overlapping portions OV of the plurality of auxiliary lines CAW disposed in a region located on the edge portion side in the second direction Y of the corner portion of the display region DA formed in the round shape is smaller than the range of the overlapping portions OV of the plurality of auxiliary lines CAW disposed in a region located on the central axis YC side in the second direction Y of the display region DA, the interval in the second direction Y of the plurality of auxiliary lines CAW connected to the power lines 51 and 52 among the plurality of auxiliary lines CAW disposed in a region located on the edge portion side in the second direction Y of the corner portion of the display region DA is larger than the interval in the second direction Y of the plurality of auxiliary lines CAW connected to the power lines 51 and 52 among the plurality of auxiliary lines CAW disposed in a region located on the central axis YC side in the second direction Y of the display region DA.

In the example shown in FIG. 9, the plurality of auxiliary lines CAW include auxiliary lines CAW1, CAW2, CAW3, CAW4, CAW5, . . . , CAWn−2, CAWn−1, CAWn, CAWn+1, CAWn+2, . . . , CAWk−4, CAWk−3, CAWk−2, CAWk−1, and CAWk.

In the example shown in FIG. 9, the plurality of auxiliary lines CAW1, CAW2, CAW3, CAW4, CAW5, . . . , CAWn−2, CAWn−1, CAWn, CAWn+1, CAWn+2, . . . , CAWk−4, CAWk−3, CAWk−2, CAWk−1, and CAWk extend in the first direction X from the display region DA to the first peripheral area N1 and the second peripheral area N2, and are arranged at intervals in the second direction Y from the edge portion ED3 side to the edge portion ED4 side in the order described. The plurality of auxiliary lines CAW1, CAW2, CAW3, CAW4, CAW5, . . . , CAWn−2, CAWn−1, CAWn, CAWn+1, CAWn+2, . . . , CAWk−4, CAWk−3, CAWk−2, CAWk−1, and CAWk are arranged at regular intervals, for example, intervals YW1 in the second direction Y. Incidentally, the plurality of auxiliary lines CAW1, CAW2, CAW3, CAW4, CAW5, . . . , CAWn−2, CAWn−1, CAWn, CAWn+1, CAWn+2, . . . , CAWk−4, CAWk−3, CAWk−2, CAWk−1, and CAWk may be arranged at different intervals in the second direction Y.

For example, the plurality of auxiliary lines CAW1, CAW2, CAW3, CAW4, and CAW5 are arranged at intervals YW1 in the second direction Y in a region AR1 having a length from the power line 51 to the power line 52 in the first direction X of the display device DSP.

For example, the plurality of auxiliary lines CAWn−2, CAWn−1, CAWn, CAWn+1, and CAWn+2 are arranged at intervals YW1 in the second direction Y in a region AR2 having a length from the power line 51 to the power line 52 in the first direction X of the display device DSP.

For example, the plurality of auxiliary lines CAWk−4, CAWk−3, CAWk−2, CAWk−1, and CAWk are arranged at intervals YW1 in the second direction Y in a region AR3 having a length from the power line 51 to the power line 52 in the first direction X of the display device DSP.

In the example shown in FIG. 9, the auxiliary line CAW1 includes an overlapping portion OV1. The auxiliary line CAW1 is electrically connected to the peripheral lines BR11 and BR21. The auxiliary line CAW2 has an overlapping portion OV2. The auxiliary line CAW2 is not electrically connected to the peripheral lines BR12 and BR22. The auxiliary line CAW3 has an overlapping portion OV3. The auxiliary line CAW3 is not electrically connected to the peripheral lines BR13 and BR23. The auxiliary line CAW4 has an overlapping portion OV4. The auxiliary line CAW4 is not electrically connected to the peripheral lines BR14 and BR24. The auxiliary line CAW5 overlaps an overlapping portion OV5. The auxiliary line CAW5 is electrically connected to the peripheral lines BR15 and BR25. The plurality of auxiliary lines CAW1, CAW2, CAW3, CAW4, and CAW5 are electrically connected to the power lines 51 and 52 at intervals YW2 in the second direction Y in the region AR1.

In the example shown in FIG. 9, the auxiliary line CAWn−2 includes an overlapping portion OVn−2. The auxiliary line CAWn−2 is electrically connected to the peripheral lines BR1(n−2) and BR2(n−2). The auxiliary line CAWn−1 has an overlapping portion OVn−1. The auxiliary line CAWn−1 is electrically connected to the peripheral lines BR1(n−1) and BR2(n−2). The auxiliary line CAWn has an overlapping portion OVn. The auxiliary line CAWn is electrically connected to the peripheral lines BR1n and BR2n. The auxiliary line CAWn+1 has an overlapping portion OVn+1. The auxiliary line CAWn+1 is electrically connected to the peripheral lines BR1(n+1) and BR2(n+1). The auxiliary line CAWn+2 has an overlapping portion OVn+2. The auxiliary line CAWn+2 is electrically connected to the peripheral lines BR1(n+2) and BR2(n+2). The plurality of auxiliary lines CAWn−2, CAWn−1, CAWn, CAWn+1, and CAWn+2 are electrically connected to the power lines 51 and 52 at intervals YW1 in the second direction Y in the region AR2. The intervals YW1 in the second direction Y in which the plurality of auxiliary lines CAWn−2, CAWn−1, CAWn, CAWn+1, and CAWn+2 disposed in the region AR2 are connected to the power lines 51 and 52 are smaller than the intervals YW2 in the second direction Y in which the plurality of auxiliary lines CAW1, CAW2, CAW3, CAW4, and CAW5 disposed in the region AR1 are connected to the power lines 51 and 52. In other words, the density of the connections of the plurality of auxiliary lines CAWn−2, CAWn−1, CAWn, CAWn+1, and CAWn+2 disposed in the region AR2 to the power lines 51 and 52 is higher than the density of the connections of the plurality of auxiliary lines CAW1, CAW2, CAW3, CAW4, and CAW5 disposed in the region AR1 to the power lines 51 and 52.

In the example shown in FIG. 9, the auxiliary line CAWk−4 includes an overlapping portion OVk−4. The auxiliary line CAWk−4 is electrically connected to the peripheral lines BR1(k−4) and BR2(k−4). The auxiliary line CAWk−3 has an overlapping portion OVk−3. The auxiliary line CAWk−3 is not electrically connected to the peripheral lines BR1(k−3) and BR2(k−3). The auxiliary line CAWk−2 has an overlapping portion OVk−2. The auxiliary line CAWk−2 is not electrically connected to the peripheral lines BR1(k−2) and BR2(k−2). The auxiliary line CAWk−1 has an overlapping portion OVk−1. The auxiliary line CAWk−1 is not electrically connected to the peripheral lines BR1(k−1) and BR2(k−1). The auxiliary line CAWk has an overlapping portion OVk. The auxiliary line CAWk is electrically connected to the peripheral lines BR1k and BR2k. The plurality of auxiliary lines CAWk−4, CAWk−3, CAWk−2, CAWk−1, and CAWk are electrically connected to the power lines 51 and 52 at intervals YW2 in the second direction Y in the region AR3. The intervals YW2 in the second direction Y in which the plurality of auxiliary lines CAWk−4, CAWk−3, CAWk−2, CAWk−1, and CAWk disposed in the region AR3 are connected to the power lines 51 and 52 are larger than the intervals YW11 in the second direction Y in which the plurality of auxiliary lines CAWn−2, CAWn−1, CAWn, CAWn+1, and CAWn+2 disposed in the region AR2 are connected to the power lines 51 and 52. In other words, the density of the connections of the plurality of auxiliary lines CAWk−4, CAWk−3, CAWk−2, CAWk−1, and CAWk disposed in the region AR3 to the power lines 51 and 52 is lower than the density of the connections of the plurality of auxiliary lines CAWn−2, CAWn−1, CAWn, CAWn+1, and CAWn+2 disposed in the region AR2 to the power lines 51 and 52.

The lengths of the overlapping portions OV1, OV2, OV3, OV4, and OV5 are shorter in the order described. The lengths of the overlapping portions OVn−2, OVn−1, OVn, OVn+1, and OVn+2 are equal. The lengths of the overlapping portions OVk−4, OVk−3, OVk−2, OVk−1, and OVk are longer in the order described. For example, the lengths of the overlapping portions OV5, OVn−2, OVn−1, OVn, OVn+1, OVn+2, and OVk−4 are equal.

For example, the voltage of the region AR1 including the auxiliary lines CAW1 to CAW5, the voltage of the auxiliary line region AR2 including the auxiliary lines CAWn−2 to CAWn+2, and the voltage of the region AR3 including the auxiliary lines CAWk−4 to CAWk are equal.

For this reason, the display device DSP according to Modified Example 3 can obtain the same effects as those of the display device DSP according to the above-described embodiment and the display devices DSP according to the above-described modified examples.

### Modified Example 4

A display device DSP according to Modified Example 4 is different from the display device DSP according to the above-described embodiment and the display devices DSP according to the above-described modified examples in the configuration of the pixels PX.

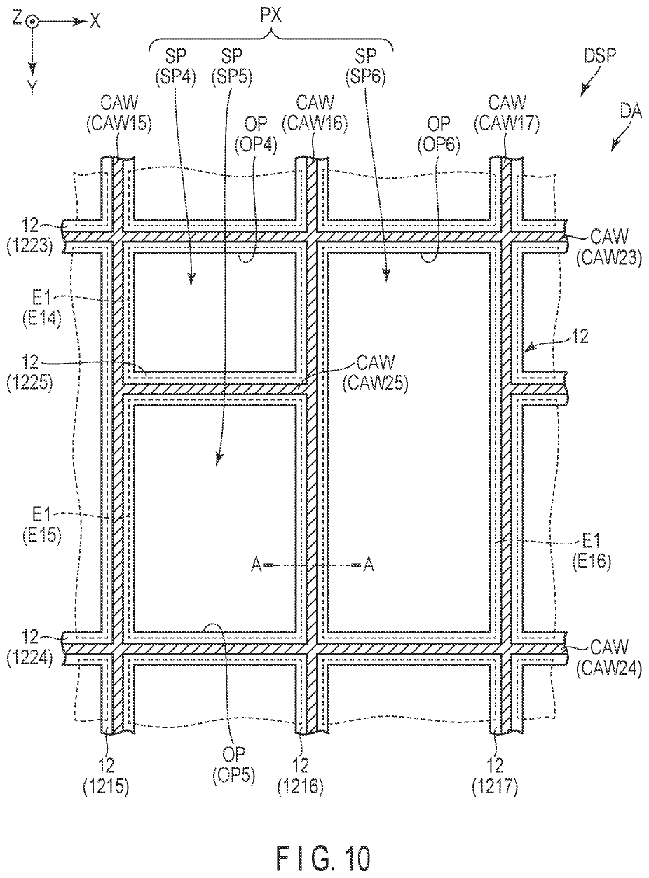

FIG. 10 is a plan view showing a configuration example of a pixel PX according to Modified Example 4. FIG. 10 shows only configurations necessary for description.

In the example shown in FIG. 10, the display device DSP includes a plurality of pixels PX arrayed in the first direction X and the second direction Y. Each of the pixels PX includes a plurality of sub-pixels SP4, SP5, and SP6. For example, each pixel PX includes a red sub-pixel SP4, a green sub-pixel SP5, and a blue sub-pixel SP6.

In the example shown in FIG. 10, the display device DSP includes an insulating layer 12 (1215, 1216, 1217, 1223, 1224, and 1225), a lower electrode E1 (E14, E15, and E16), an auxiliary line CAW (CAW15, CAW16, CAW17, CAW23, CAW24, and CAW25), and the like.

In the example shown in FIG. 10, the lower electrode E1 includes lower electrodes E14, 515, and E16. The lower electrode 514 is disposed at the sub-pixel SP4. The lower electrode 515 is disposed at the sub-pixel SP5. The lower electrode 516 is disposed at the sub-pixel SP6. The lower electrodes 514 and 515 are arranged in the second direction Y. The lower electrodes 514 and 515 and the lower electrode 516 are arranged in the first direction X.

In the example shown in FIG. 10, the insulating layer 12 includes insulating layers (banks) 1215, 1216, 1217, 1223, 1224, and 1225. The insulating layers 1215, 1216, and 1217 extend in the second direction Y. The insulating layers 1215 to 1217 are arranged at intervals in the first direction X. For example, the insulating layers 1215, 1216, and 1217 are arranged in the order described toward the distal part side of the arrow in the first direction X. The insulating layers 1223, 1224, and 1225 extend in the first direction X. The insulating layer 1225 is shorter than the insulating layers 1223 and 1224. For example, the length of the insulating layer 1225 corresponds to the interval between the insulating layers 1215 and 1216 in the first direction X. The insulating layers 1223 to 1225 are arranged at intervals in the second direction Y. For example, the insulating layers 1223, 1225, and 1224 are arranged in the order described toward the distal part side of the arrow in the second direction Y. The insulating layers 1215 to 1217 intersect the insulating layers 1223 and 1224. The insulating layers 1215 and 1216 intersect the insulating layer 1225.

In the example shown in FIG. 10, the insulating layer 12 has an opening portion OP4 overlapping the lower electrode E14, an opening portion OP5 overlapping the lower electrode E15, and an opening portion OP6 overlapping the lower electrode E16. The opening portion OP4 corresponds to a region surrounded by the insulating layers 1215 and 1216 and the insulating layers 1223 and 1225. In other words, the central portion of the lower electrode E14 overlapping the opening portion OP4 is exposed from the insulating layer 12. The opening portion OP5 corresponds to a region surrounded by the insulating layers 1215 and 1216 and the insulating layers 1225 and 1224. In other words, the central portion of the lower electrode E15 overlapping the opening portion OP5 is exposed from the insulating layer 12. The opening portion OP6 corresponds to a region surrounded by the insulating layers 1216 and 1217 and the insulating layers 1223 and 1224. In other words, the central portion of the lower electrode E16 overlapping the opening portion OP6 is exposed from the insulating layer 12.

In the example shown in FIG. 10, the insulating layer 1223 overlaps the end portion of the lower electrode E14 on the side opposite to the distal part side of the arrow in the second direction Y and the end portion of the lower electrode E16 on the side opposite to the distal part side of the arrow in the second direction Y. The insulating layer 1224 overlaps the end portion of the lower electrode E15 on the distal part side of the arrow in the second direction Y and the end portion of the lower electrode E16 on the distal part side of the arrow in the second direction Y. The insulating layer 1225 overlaps the end portion of the lower electrode E14 on the distal part side of the arrow in the second direction Y and the end portion of the lower electrode E15 on the side opposite to the distal part side of the arrow in the second direction Y. The insulating layer 1215 overlaps the end portion of the lower electrode E14 on the side opposite to the distal part side of the arrow in the first direction X and the end portion of the lower electrode E15 on the side opposite to the distal part side of the arrow in the first direction X. The insulating layer 1216 overlaps the end portion of the lower electrode E14 on the distal part side of the arrow in the first direction X, the end portion of the lower electrode E15 on the distal part side of the arrow in the first direction X, and the end portion of the lower electrode E16 on the side opposite to the distal part side of the arrow in the first direction X. The insulating layer 1217 overlaps the end portion of the lower electrode E16 on the distal part side of the arrow in the first direction X.

In the example shown in FIG. 10, the auxiliary line CAW includes auxiliary lines CAW15, CAW16, CAW17, CAW23, CAW24, and CAW25. The auxiliary lines CAW15, CAW16, and CAW17 extend in the second direction Y. The auxiliary lines CAW15 to CAW17 are arranged at intervals in the first direction X. For example, the auxiliary lines CAW15, CAW16, and CAW17 are arranged in the order described toward the distal part side of the arrow in the first direction X. The auxiliary lines CAW23, CAW24, and CAW25 extend in the first direction X. The auxiliary line CAW25 is shorter than the auxiliary lines CAW23 and CAW24. For example, the length of the auxiliary line CAW25 corresponds to the interval between the auxiliary line CAW15 and the auxiliary line CAW16 in the first direction X. The auxiliary lines CAW23 to CAW25 are arranged at intervals in the second direction Y. For example, the auxiliary lines CAW23, CAW25, and CAW24 are arranged in the order described toward the distal part side of the arrow in the second direction Y. The auxiliary lines CAW15 to CAW17 intersect the auxiliary lines CAW23 and CAW24. The auxiliary lines CAW15 and CAW16 intersect the auxiliary line CAW25.

The auxiliary line CAW15 overlaps the insulating layer 1215, the auxiliary line CAW16 overlaps the insulating layer 1216, and the auxiliary line CAW17 overlaps the insulating layer 1217. The auxiliary line CAW23 overlaps the insulating layer 1223, the auxiliary line CAW24 overlaps the insulating layer 1224, and the auxiliary line CAW25 overlaps the insulating layer 1225. The auxiliary lines CAW15 to CAW17 and the auxiliary lines CAW23 to CAW25 do not overlap the lower electrode E1.

In this case, the sub-pixel SP4 is formed in an approximately rectangular shape extending in the first direction X, the sub-pixel SP5 is formed in a substantially rectangular shape extending in the second direction Y, and the sub-pixel SP6 is formed in an approximately rectangular shape extending in the second direction Y. The width of the sub-pixel SP4 in the first direction X is the same as the width of the sub-pixel SP5 in the first direction X. The width of the sub-pixel SP6 in the second direction Y is substantially the same as the total width of the width of the sub-pixel SP4 in the second direction Y and the width of the sub-pixel SP5 in the second direction Y. The areas of the sub-pixels SP4 to SP6 are different from each other. The area of the sub-pixel SP5 is larger than the area of the sub-pixel SP4, and the area of the sub-pixel SP6 is larger than the area of the sub-pixel SP5. Incidentally, the area of the sub-pixel SP5 may be the same as the area of the sub-pixel SP4. For this reason, the display device DSP according to Modified Example 4 can obtain the same effects as those of the display device DSP according to the above-described embodiment and the display devices DSP according to the above-described modified examples.

### Modified Example 5

A display device DSP according to Modified Example 5 is different from the display device DSP according to the above-described embodiment and the display devices DSP according to the above-described modified examples in the configuration of the pixels PX.

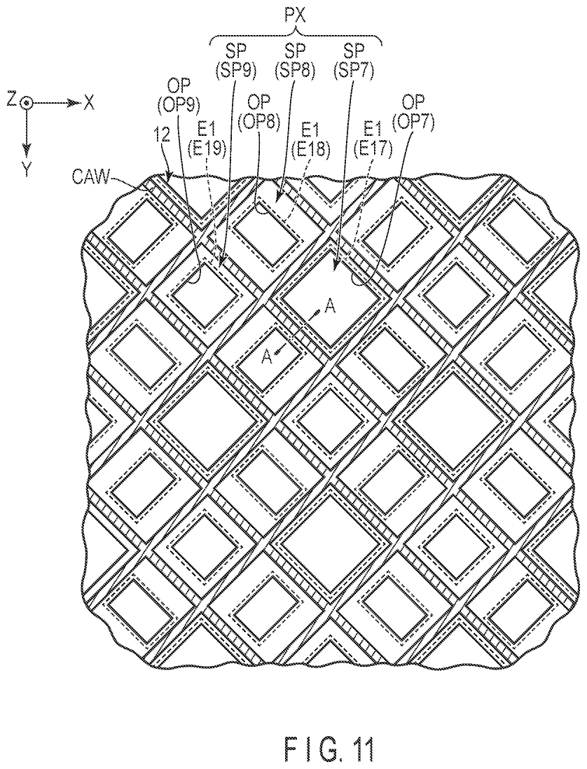

FIG. 11 is a plan view showing a configuration example of a pixel PX according to Modified Example 5. FIG. 11 shows only configurations necessary for description.

In the example shown in FIG. 11, the display device DSP includes a plurality of pixels PX arrayed in a diamond pattern in the first direction X and the second direction Y. The pixels PX correspond to, for example, pentile pixels in which a plurality of pixels PX adjacent to each other shares a sub-pixel SP. Each of the pixels PX includes a plurality of sub-pixels SP7, SP8, and SP9. For example, each of the pixels PX includes a blue sub-pixel SP7, a green sub-pixel SP8, and a red sub-pixel SP9.

In the example shown in FIG. 11, the display device DSP includes an insulating layer 12, a lower electrode E1 (E17, E18, and E19), an auxiliary line CAW, and the like.

In the example shown in FIG. 11, the lower electrode E1 includes lower electrodes E17, E18, and E19. The lower electrode E17 is disposed at the sub-pixel SP7. The lower electrode E18 is disposed at the sub-pixel SP8. The lower electrode E19 is disposed at the sub-pixel SP9. The lower electrodes E17 to E19 are disposed in a triangular pattern in planar view. The lower electrode E17 is disposed on the distal part side of the arrow in the first direction X and on the distal part side of the arrow in the second direction Y with respect to the lower electrode E18 in planar view. The lower electrode E19 is disposed on the side opposite to the distal part side of the arrow in the first direction X and on the distal part side of the arrow in the second direction Y with respect to the lower electrode 518 in planar view. The shapes of the lower electrodes 517 to 519 are different. Incidentally, the shapes of two lower electrodes E1 among the lower electrodes E11 to E19 may be the same. The areas of the lower electrodes E11 to E19 are different. Incidentally, the areas of two lower electrodes E1 among the lower electrodes E11 to E19 may be the same.

In the example shown in FIG. 11, the insulating layer 12 is formed in an oblique lattice pattern in planar view. The insulating layer 12 has an opening portion OP7 overlapping the lower electrode E17, an opening portion OP8 overlapping the lower electrode E18, and an opening portion OP9 overlapping the lower electrode E19. The central portion of the opening portion OP7 is exposed from the insulating layer 12. The central portion of the opening portion OP8 is exposed from the insulating layer 12. The central portion of the opening portion OP9 is exposed from the insulating layer 12.

In the example shown in 11, the auxiliary line CAW is disposed in an oblique lattice pattern so as to overlap the insulating layer 12 in planar view.

In this case, the outer shape of the sub-pixel SP7 corresponds to the outer shape of the lower electrode E17. For example, the outer shape of the sub-pixel SP7 is a square shape. Incidentally, the outer shape of the sub-pixel SP7 may be a shape other than the square shape. The outer shape of the sub-pixel SP8 corresponds to the outer shape of the lower electrode E18. For example, the outer shape of the sub-pixel SP8 is a rectangular shape. Incidentally, the outer shape of the sub-pixel SP8 may be a shape other than the rectangular shape. The outer shape of the sub-pixel SP9 corresponds to the outer shape of the lower electrode E19. For example, the outer shape of the sub-pixel SP9 is a square shape. Incidentally, the outer shape of the sub-pixel SP9 may be a shape other than the square shape. The area of the sub-pixel SP7 is larger than the areas of the sub-pixels SP8 and SP9. The area of the sub-pixel SP8 is equal to or smaller than the area of the sub-pixel SP9. Incidentally, the area of the sub-pixel SP8 may be larger than the area of the sub-pixel SP9.

For this reason, the display device DSP according to Modified Example 5 can obtain the same effects as those of the display device DSP according to the above-described embodiment and the display devices DSP according to the above-described modified examples.

For each of the display devices DSP according to the above-described embodiment and the above-described modified examples, only the connection state between the auxiliary lines CAW extending in the first direction X and the peripheral lines BR has been described, but the same configuration as that of the auxiliary lines CAW extending in the first direction X can also be applied to auxiliary lines CAW extending in the second direction Y.

Based on the display device which has been described in the above-described embodiments, a person having ordinary skill in the art may achieve a display device with an arbitral design change; however, as long as they fall within the scope and spirit of the present invention, such a display device is encompassed by the scope of the present invention.

Furthermore, regarding the present embodiments, any advantage and effect those will be obvious from the description of the specification or arbitrarily conceived by a skilled person are naturally considered achievable by the present invention.

For example, if a skilled person adds/deletes/alters a structural element or design to/from/in the above-described embodiments, or adds/deletes/alters a step or a condition to/from/in the above-described embodiment, as long as they fall within the scope and spirit of the present invention, such addition, deletion, and altercation are encompassed by the scope of the present invention.

A skilled person would conceive various changes and modifications of the present invention within the scope of the technical concept of the invention, and naturally, such changes and modifications are encompassed by the scope of the present invention.

What is claimed is:

1. A display device comprising:
a first power line located at a first end portion of a non-display region located around a display region in which a plurality of pixels are disposed and that includes a rounded corner portion;
a second power line located at a second end portion on a side opposite to the first end portion of the non-display region in a first direction;
a first auxiliary line extending in the first direction, connected to the first power line and the second power line, and disposed at the corner portion; and
a second auxiliary line extending in the first direction, connected to the first power line and the second power line, and disposed on a center portion side of the display region in a second direction intersecting the first direction, wherein
the first auxiliary line includes a first resistance adjustment portion that is located in the non-display region and adjusts resistance of the first auxiliary line,
the second auxiliary line includes a second resistance adjustment portion that is located in the non-display region and adjusts resistance of the second auxiliary line, and
a first length of the first resistance adjustment portion is longer than a second length of the second resistance adjustment portion.

2. The display device according to claim 1, wherein a third length of a part where the first auxiliary line overlaps the display region is shorter than a fourth length of a part where the second auxiliary line overlaps the display region.

3. The display device according to claim 2, wherein a first number of pixels that the first auxiliary line overlaps is smaller than a second number of pixels that the second auxiliary line overlaps.

4. The display device according to claim 1, wherein the first resistance adjustment portion and the second resistance adjustment portion have a zigzag shape.

5. The display device according to claim 1, wherein the first resistance adjustment portion and the second resistance adjustment portion have a width smaller than the display region.

6. The display device according to claim 1, wherein the first auxiliary line and the second auxiliary line include a transparent material containing indium tin oxide or indium zinc oxide.

7. The display device according to claim 1, further comprising:
a substrate;
a first insulating layer disposed on the substrate;
a first lower electrode disposed on the first insulating layer;
a second lower electrode that is disposed on the first insulating layer, is separated from the first lower electrode, and is formed of the same material as the first lower electrode;
a second insulating layer disposed on the first lower electrode and the second lower electrode;
a first organic layer disposed on the first lower electrode and including a light emitting layer;
a second organic layer disposed on the second lower electrode and including the light emitting layer;
a first upper electrode disposed on the first organic layer;
a second upper electrode disposed on the second organic layer; and
the first auxiliary line disposed on the second insulating layer.

8. A display device comprising:
a first power line located at a first end portion of a non-display region located around a display region in which a plurality of pixels are disposed and that includes a rounded corner portion;
a second power line located at a second end portion on a side opposite to the first end portion of the non-display region in a first direction;
a plurality of first auxiliary lines extending in the first direction and disposed in a first region including the corner portion of the display region; and
a plurality of second auxiliary lines extending in the first direction and disposed in a second region including a central portion of the display region in a second direction intersecting the first direction, wherein
the first auxiliary lines are connected to the first power line and the second power line at a first interval in the second direction, and
the second auxiliary lines are connected to the first power line and the second power line at a second interval smaller than the first interval in the second direction.

9. The display device according to claim 8, wherein a first number of pixels that the first auxiliary lines overlap is smaller than a second number of pixels that the second auxiliary lines overlap.

10. The display device according to claim 8, wherein the first auxiliary lines and the second auxiliary lines include a transparent material containing indium tin oxide or indium zinc oxide.

11. The display device according to claim 8, further comprising:
a substrate;
a first insulating layer disposed on the substrate;
a first lower electrode disposed on the first insulating layer;
a second lower electrode that is disposed on the first insulating layer, is separated from the first lower electrode, and is formed of the same material as the first lower electrode;
a second insulating layer disposed on the first lower electrode and the second lower electrode;
a first organic layer disposed on the first lower electrode and including a light emitting layer;
a second organic layer disposed on the second lower electrode and including the light emitting layer;
a first upper electrode disposed on the first organic layer;
a second upper electrode disposed on the second organic layer; and
the first auxiliary lines disposed on the second insulating layer.

12. A display device comprising:
a first power line located at a first end portion of a non-display region located around a display region in which a plurality of pixels are disposed and that includes a rounded corner portion;
a second power line located at a second end portion on a side opposite to the first end portion of the non-display region in a first direction;
a first peripheral line located in the non-display region, extending in the first direction, and connected to the first power line;
a second peripheral line located in the non-display region, extending in the first direction, and connected to the second power line;
a third peripheral line located closer to a central portion of the display region than the first peripheral line is in a second direction intersecting the first direction in the non-display region, extending in the first direction, and connected to the first power line;
a fourth peripheral line located closer to the central portion of the display region than the second peripheral line is in the second direction in the non-display region, extending in the first direction, and connected to the second power line;
a first auxiliary line extending in the first direction, connected to the first peripheral line and the third peripheral line, and disposed at the corner portion; and
a second auxiliary line extending in the first direction and connected to the second peripheral line and the fourth peripheral line, wherein
the first peripheral line and the third peripheral line include a first resistance adjustment portion that adjusts resistance from the first peripheral line to the third peripheral line,
the second peripheral line and the fourth peripheral line include a second resistance adjustment portion that adjusts resistance from the second peripheral line to the fourth peripheral line, and
a first length of the first resistance adjustment portion is longer than a second length of the second resistance adjustment portion.

13. The display device according to claim 12, wherein a third length of a part where the first auxiliary line overlaps the display region is shorter than a fourth length of a part where the second auxiliary line overlaps the display region.

14. The display device according to claim 13, wherein a first number of pixels that the first auxiliary line overlaps is smaller than a second number of pixels that the second auxiliary line overlaps.

15. The display device according to claim 12, wherein the first resistance adjustment portion and the second resistance adjustment portion have a zigzag shape.
